(19) United States
(12) Patent Application Publication
(10) Pub. No.: US 2024/0079389 A1
(43) Pub. Date: Mar. 7, 2024

(54) DISPLAY PANEL AND ELECTRONIC APPARATUS INCLUDING THE SAME

(71) Applicant: Samsung Display Co., Ltd., Yongin-si (KR)

(72) Inventors: Donghyeon Jang, Yongin-si (KR); Wonse Lee, Yongin-si (KR); Yujin Jeon, Yongin-si (KR)

(73) Assignee: Samsung Display Co., Ltd., Yongin-si (KR)

(21) Appl. No.: 18/459,798

(22) Filed: Sep. 1, 2023

(30) Foreign Application Priority Data
Sep. 1, 2022 (KR) 10-2022-0111011

(51) Int. Cl. H01L 25/075; H01L 25/16; H01L 27/12; H01L 33/62; H04M 1/02

(52) U.S. Cl. CPC H01L 25/0753; H01L 25/167; H01L 27/124; H01L 33/62; H04M 1/0264

(57) ABSTRACT

Provided is a display panel including a plurality of first light-emitting diodes in a first display area and respectively electrically connected to a plurality of first sub-pixel circuits, a plurality of second light-emitting diodes located in a second display area inside the first display area and including a transmissive area, and a plurality of second sub-pixel circuits in an area different from the second display area and electrically connected to the plurality of second light-emitting diodes, wherein the plurality of first and second light-emitting diodes each include light-emitting diodes of a first color, light-emitting diodes of a second color, and light-emitting diodes of a third color, and a first width of an emission area of a light-emitting diode of the first color in the second display area is greater than a second width of an emission area of a light-emitting diode of the first color in the first display area.

### BACKGROUND

### 1. Field

One or more embodiments relate to a display panel and a structure for an electronic apparatus including the same.

### 2. Description of the Related Art

A display panel is an apparatus configured to visually display data. Recently, the usage of display panels has diversified. As display panels have become thinner and lighter, their range of use has been gradually extended.

As an alternative for adding various functions while increasing an area occupied by a display area, research has been carried out on a display panel for adding various functions other than displaying images inside the display area.

### SUMMARY

One or more embodiments include a display panel including a transmissive area inside a display area, and a structure for an electronic apparatus including the display panel.

Additional aspects will be set forth in part in the description which follows and, in part, will be apparent from the description, or may be learned by practice of the presented embodiments of the disclosure.

According to one or more embodiments, a display panel includes a plurality of first light-emitting diodes arranged in a first display area a plurality of first sub-pixel circuits arranged in the first display area and respectively electrically connected to the plurality of first light-emitting diodes a plurality of second light-emitting diodes arranged in a second display area inside the first display area and including a transmissive area and a plurality of second sub-pixel circuits arranged in an area different from the second display area and respectively electrically connected to the plurality of second light-emitting diodes, wherein the plurality of first light-emitting diodes and the plurality of second light-emitting diodes each include light-emitting diodes of a first color, light-emitting diodes of a second color, and light-emitting diodes of a third color, and a first width of an emission area of a light-emitting diode of the first color arranged in the second display area is greater than a second width of an emission area of a light-emitting diode of the first color arranged in the first display area.

A first electrode of the light-emitting diode of the first color, arranged in the second display area may be electrically connected to a first electrode of an adjacent light-emitting diode of the first color through a first connection line.

The first electrode of the light-emitting diode of the first color and the first electrode of the adjacent light-emitting diode of the first color may each include a plurality of sub-layers, and the first connection line may be integrally coupled to one of the plurality of sub-layers.

The light-emitting diode of the first color and the adjacent light-emitting diode of the first color electrically connected to each other through the first connection line may be electrically connected to one of the plurality of second sub-pixel circuits.

The plurality of second sub-pixel circuits may be arranged in a third display area between the first display area and the second display area.

The display panel may further include a conductive bus line electrically connecting the light-emitting diode of the first color arranged in the second display area to one of the plurality of second sub-pixel circuits, wherein the conductive bus line may extend from the third display area to the second display area.

The conductive bus line may include a light transmissive conductive material.

The first width of the emission area of the light-emitting diode of the first color arranged in the second display area may be greater than a width of an emission area of the light-emitting diode of the second color arranged in the second display area, and the second width of the emission area of the light-emitting diode of the first color arranged in the first display area may be less than a width of an emission area of the light-emitting diode of the second color arranged in the first display area.

A number of light-emitting diodes of the first color arranged in the second display area may be less than a number of light-emitting diodes of the first color arranged in the first display area, a number of light-emitting diodes of the second color arranged in the second display area may be equal to a number of light-emitting diodes of the second color arranged in the first display area per same area, and a number of light-emitting diodes of the third color arranged in the second display area per same area may be equal to a number of light-emitting diodes of the third color arranged in the first display area per same area.

Light-emitting diodes of the first color around the light-emitting diode of the second color in the second display area may be located at only two vertexes among four vertexes of a virtual quadrangle with the light-emitting diode of the second color centered in the second display area.

Light-emitting diodes of the first color around the light-emitting diode of the second color in the first display area may be respectively located at four vertexes of a virtual quadrangle with the light-emitting diode of the second color centered in the first display area.

According to one or more embodiments, an electronic apparatus includes a display panel including a first display area, a second display area, and a third display area, the second display area being surrounded by the first display area, and the third display area being between the first display area and the second display area and a component disposed below the display panel and corresponding to the second display area, wherein the display panel includes a plurality of first light-emitting diodes arranged in the first display area a plurality of first sub-pixel circuits arranged in the first display area and respectively electrically connected to the plurality of first light-emitting diodes a plurality of second light-emitting diodes arranged in the second display area and a plurality of second sub-pixel circuits arranged in the third display area and respectively electrically connected to the plurality of second light-emitting diodes, wherein the plurality of first light-emitting diodes and the plurality of second light-emitting diodes each include light-emitting diodes of a first color, light-emitting diodes of a second color, and light-emitting diodes of a third color, and a first width of an emission area of a light-emitting diode of the first color arranged in the second display area is greater than a second width of an emission area of a light-emitting diode of the first color arranged in the first display area.

A number of light-emitting diodes of the first color arranged in the second display area may be less than a number of light-emitting diodes of the first color arranged in the first display area per same area.

A first electrode of the light-emitting diode of the first color, arranged in the second display area may be electrically connected to a first electrode of an adjacent light-emitting diode of the first color through a first connection line.

The first electrode of the light-emitting diode of the first color and the first electrode of the adjacent light-emitting diode of the first color may each include a plurality of sub-layers, and the first connection line may be integrally coupled to one of the plurality of sub-layers.

The first electrode of the light-emitting diode of the first color may be electrically connected to one of the plurality of second sub-pixel circuits through a conductive bus line extending from the third display area to the second display area.

The conductive bus line may include a transparent conductive material.

Light-emitting diodes of the first color around the light-emitting diode of the second color in the second display area may be located at only two vertexes among four vertexes of a virtual quadrangle with the light-emitting diode of the second color centered in the second display area.

Light-emitting diodes of the first color around the light-emitting diode of the second color in the first display area may be respectively located at four vertexes of a virtual quadrangle with the light-emitting diode of the second color centered in the first display area.

The component may include a sensor or a camera.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of an electronic apparatus according to an embodiment;

FIG. 2 is a schematic cross-sectional view of an electronic apparatus according to an embodiment;

FIG. 3 is a schematic plan view of a display panel according to an embodiment;

FIG. 4 is a schematic equivalent circuit diagram of a sub-pixel circuit electrically connected to a light-emitting diode of the display panel according to an embodiment;

FIG. 5 is a plan view of first sub-pixels arranged in a first display area of a display panel according to an embodiment;

FIG. 6A is a plan view of second sub-pixels and third sub-pixels arranged in a second display area and a third display area of a display panel according to an embodiment;

FIG. 6B is a plan view of a configuration of second and third sub-pixels arranged in second and third display areas of a display panel according to an embodiment;

FIG. 7 is a plan view of a portion of a display panel according to an embodiment;

FIG. 8A is a view of sub-pixel circuits located in a region VIII of FIG. 7 as a portion of a display panel according to an embodiment;

FIG. 8B is a view of light-emitting diodes on sub-pixel circuits located in the region VIII of FIG. 7 as a portion of a display panel according to an embodiment;

FIG. 8C is a view of light-emitting diodes on sub-pixel circuits located in the region VIII of FIG. 7 as a portion of a display panel according to another embodiment;

FIGS. 9A and 9B are plan views showing second light-emitting diodes of a display panel are electrically connected to second sub-pixel circuits through conductive bus lines according to an embodiment;

FIG. 10 is a cross-sectional view of a display panel according to an embodiment and shows electrical connection between a first sub-pixel circuit and a first light-emitting diode; and

FIG. 11 is a cross-sectional view of a display panel according to an embodiment and shows electrical connection between a second sub-pixel circuit and a second light-emitting diode.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” or “at least one of of a, b and c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

It will be understood that when a layer, region, or element is referred to as being “connected” to another layer, region, or element, it may be “directly connected” to the other layer, region, or element or may be “indirectly connected” to the other layer, region, or element with other layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to other layer, region, or element with other layer, region, or element located therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

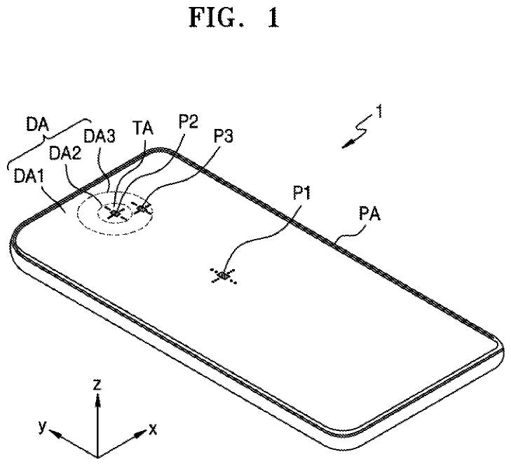

FIG. 1 is a schematic perspective view of an electronic apparatus 1 according to an embodiment.

Referring to FIG. 1, the electronic apparatus 1 may include a display area DA and a peripheral area PA outside the display area DA. The display area DA may be configured to display images using sub-pixels. The peripheral area PA is arranged outside the display area DA, and a non-display area in which images are not displayed. The peripheral area PA may surround the display area DA entirely. A driver and the like configured to provide electric signals or power to the display area DA may be arranged in the peripheral area PA. A pad may be arranged in the peripheral area PA, wherein the pad is a region to which electronic elements or a printed circuit board may be electrically connected.

Hereinafter, for convenience of description, though the case where the electronic apparatus 1 is a smartphone is described, the electronic apparatus 1 according to an embodiment is not limited thereto. The electronic apparatus 1 is applicable to various products including televisions, notebook computers, monitors, advertisement boards, Internet of things (loTs) as well as portable electronic apparatuses including mobile phones, smart phones, tablet personal computers (PCs), mobile communication terminals, electronic organizers, electronic books, portable multimedia players (PMPs), navigations, and ultra mobile personal computers (UMPCs). In addition, the electronic apparatus 1 is applicable to wearable devices including smartwatches, watchphones, glasses-type displays, and head-mounted displays (HMDs). In addition, in an embodiment, the electronic apparatus 1 is applicable to instrument panels for automobiles, center fascias for automobiles, or center information displays (CIDs) arranged on a dashboard, room mirror displays that replace side mirrors of automobiles, and displays arranged on the backside of front seats as an entertainment for back seats of automobiles.

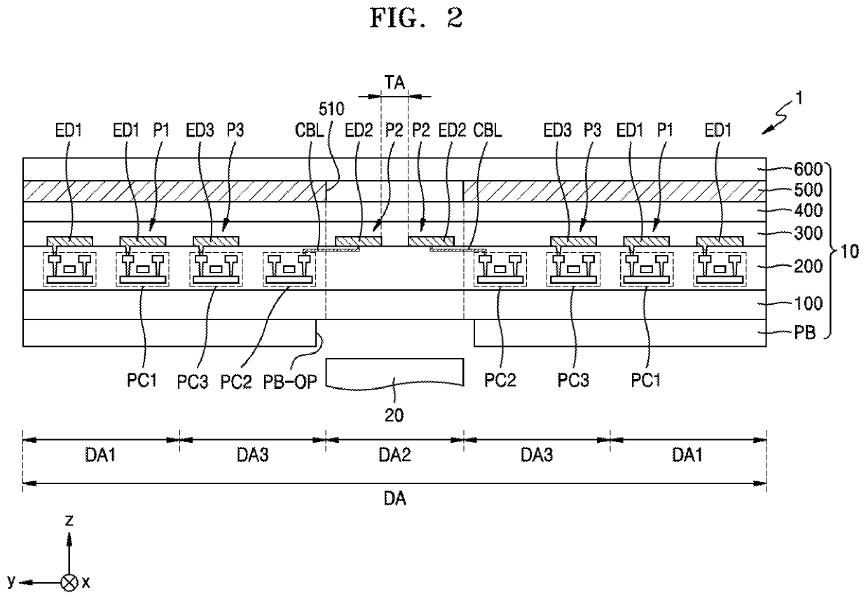

The display area DA may include a first display area DA1 and a second display area DA2, the first display area DA1 occupying most of the display area DA, and the second display area DA2 corresponding to a component described below with reference to FIG. 2. The first display area DA1 may occupy most of the area of the display area DA. When the first display area DA1 occupies most of the area of the display area DA, it means that the area of the first display area DA1 is 50% or more of the area of the display area DA.

The second display area DA2 may be arranged inside the first display area DA1, and surrounded by the first display area DA1 entirely. The display area DA may include a third display area DA3 between the first display area DA1 and the second display area DA2. The third display area DA3 may surround the second display area DA2, and the first display area DA1 may surround the third display area DA3.

The display area DA may be configured to display images by using sub-pixels arranged two-dimensionally. In the present specification, among sub-pixels arranged in the display area DA, sub-pixels arranged in the first display area DA1 are referred to as first sub-pixels P1, sub-pixels arranged in the second display area DA2 are referred to as second sub-pixels P2, and sub-pixels arranged in the third display area DA3 are referred to as third sub-pixels P3.

The second display area DA2 and the third display area DA3 may each have a smaller area than the area of the first display area DA1. Though it is shown in FIG. 1 that the second display area DA2 and the third display area DA3 each have a circular shape, the second display area DA2 and the third display area DA3 may each have an approximately quadrangular shape in another embodiment.

Though it is shown in FIG. 1 that the second display area DA2 and the third display area DA3 are arranged in the center in the upper side (a +y direction) of the display area DA having an approximately quadrangular shape when viewed in a direction approximately perpendicular to the upper surface of the electronic appartus 1, the embodiment is not limited thereto. The second display area DA2 and the third display area DA3 may be arranged, for example, on the upper right side or upper left side of the display area DA.

The second display area DA2 may be configured to display images by using the second sub-pixels P2, and transmit light and/or sound through regions between the second sub-pixels P2. Hereinafter, a region that may transmit light or sound is referred to as a transmissive area TA. In other words, the second display area DA2 may include the transmissive area TA between the second sub-pixels P2.

FIG. 2 is a schematic cross-sectional view of the electronic apparatus 1 according to an embodiment.

Referring to FIG. 2, the electronic apparatus 1 may include a display panel 10 and a component 20 overlapping the display panel 10. The component 20 may be arranged in the second display area DA2.

The component 20 may be an electronic element that uses light or sound. As an example, the electronic element may be a sensor that measures a distance such as a proximity sensor, a sensor that recognizes a portion of a user's body (e.g., a fingerprint, an iris, a face and the like), a small lamp that outputs light, or an image sensor (e.g., a camera) that photographs images. The electronic element that uses light may use light in various wavelength bands such as visible light, infrared light, ultraviolet light and the like. The electronic element that uses sound may use ultrasonic waves or sound in different frequency bands.

The second display area DA2 may include the transmissive area TA through which light and/or sound that is output from the component 20 to the outside or that progresses toward the component 20 from the outside, may pass. In an embodiment, the transmissive area TA is a region through which light may pass and may correspond to regions between the second sub-pixels P2. In the electronic apparatus 1 according to an embodiment, in the case where light is transmitted through the second display area DA2 including the transmissive area TA, a light transmittance may be 10% or more, more preferably 25% or more, 40% or more, 50% or more, 85% or more, or 90% or more.

The first sub-pixel P1, the second sub-pixel P2, and the third sub-pixel P3 described above with reference to FIG. 1 may each be configured to emit light by using a light-emitting diode, and each light-emitting diode may be arranged in the display area DA of the display panel 10. With regard to this, in the present specification, a light-emitting diode corresponding to the first sub-pixel P1 and arranged in the first display area DA1 is referred to as a first light-emitting diode ED1, a light-emitting diode corresponding to the second sub-pixel P2 and arranged in the second display area DA2 is referred to as a second light-emitting diode ED2, and a light-emitting diode corresponding to the third sub-pixel P3 and arranged in the third display area DA3 is referred to as a third light-emitting diode ED3. The first to third light-emitting diodes ED1, ED2, and ED3 may be arranged over the substrate 100.

The substrate 100 may include an insulating material such as glass or polymer resin. A protective film PB may be disposed on the backside of the substrate 100. The substrate 100 may be a rigid substrate or a flexible substrate that is bendable, foldable, and rollable. The protective film PB may include an opening PB-OP located in the second display area DA2 to improve a transmittance of the transmissive area TA.

The first light-emitting diode ED1 is arranged in the first display area DA1 and electrically connected to a first sub-pixel circuit PC1 arranged in the first display area DA1. The first sub-pixel circuit PC1 may include transistors and a storage capacitor electrically connected to the transistors.

The second light-emitting diode ED2 is arranged in the second display area DA2. The second light-emitting diode ED2 is electrically connected to a second sub-pixel circuit PC2. The second sub-pixel circuit PC2 is not arranged in the second display area DA2 to improve a transmittance and a transmissive area of the transmissive area TA in the second display area DA2. The second sub-pixel circuit PC2 is arranged in the third display area DA3. The second light-emitting diode ED2 may be electrically connected to the second sub-pixel circuit PC2 through a conductive bus line CBL.

The conductive bus line CBL may electrically connect the second sub-pixel circuit PC2 in the third display area DA3 to the second light-emitting diode ED2 in the second display area DA2. The conductive bus line CBL may include a light transmissive conductive material, for example, a transparent conductive oxide TCO. The transparent conductive oxide TCO may include indium tin oxide (ITO), indium zinc oxide (IZO), zinc oxide (ZnO), indium oxide (In2O3), indium gallium oxide (IGO), and/or aluminum zinc oxide (AZO).

The third light-emitting diode ED3 is arranged in the third display area DA3 and electrically connected to a third sub-pixel circuit PC3 arranged in the third display area DA3. The third sub-pixel circuit PC3 may include transistors and a storage capacitor electrically connected to the transistors.

The first to third light-emitting diodes ED1, ED2, and ED3 are light-emitting elements that emit light of a preset color, and may include organic light-emitting diodes. In another embodiment, the first to third light-emitting diodes ED1, ED2, and ED3 may be inorganic light-emitting diodes in which an emission layer includes an inorganic material, or quantum-dot light-emitting diodes in which an emission layer includes quantum dots.

The first to third light-emitting diodes ED1, ED2, and ED3 may be covered by an encapsulation layer 300. The encapsulation layer 300 may be a thin-film encapsulation layer including an inorganic encapsulation layer and an organic encapsulation layer, wherein the inorganic encapsulation layer includes an inorganic insulating material, and the organic encapsulation layer includes an organic insulating material. In an embodiment, the encapsulation layer 300 may include a first inorganic encapsulation layer, a second inorganic encapsulation layer, and an organic encapsulation layer therebetween.

In another embodiment, the encapsulation layer 300 may be an encapsulation substrate such as glass. Sealant such as frit and the like may be disposed between the substrate 100 and the encapsulation substrate. The sealant may be located in the peripheral area PA and may extend to surround the outer edges of the display area DA to prevent moisture from penetrating toward the first to third light-emitting diodes ED1, ED2, and ED3 through the lateral surface.

An input sensing layer 400 may be disposed on the encapsulation layer 300. The input sensing layer 400 may obtain coordinate information corresponding to an external input, for example, a touch event of a finger or an object such as a stylus pen. The input sensing layer 400 may include a touch electrode and touch lines connected to the touch electrode. The input sensing layer 400 may sense an external input by using a self-capacitance method and/or a mutual capacitance method.

An optical functional layer 500 may include an anti-reflection layer. The anti-reflection layer may reduce the reflectivity of light (external light) incident toward the display panel 10 from the outside through a cover window 600. The anti-reflection layer may include a retarder and a polarizer. In the case where the optical functional layer 500 includes a polarizer, the optical functional layer 500 may include an opening 510 located in the second display area DA2, and thus, improve a transmittance of the transmissive area TA.

In another embodiment, the anti-reflection layer may include a black matrix and color filters. The color filters may be arranged by taking into account colors of light emitted from the first to third light-emitting diodes ED1, ED2, and ED3, respectively. In the case where the optical functional layer 500 includes the black matrix and the color filters, a light transmissive material may be arranged in a position corresponding to the transmissive area TA.

In another embodiment, the anti-reflection layer may include a destructive interference structure. The destructive interference structure may include a first reflection layer and a second reflection layer respectively disposed on different layers. First-reflected light and second-reflected light respectively reflected by the first reflection layer and the second reflection layer may destructively interfere and thus the reflectivity of external light may be reduced.

The cover window 600 may be disposed on the optical functional layer 500. The cover window 600 may be coupled to the optical functional layer 500 by an adhesive layer such as a transparent optical clear adhesive disposed between the cover window 600 and the optical functional layer 500. The cover window 600 may include glass and/or plastic. The plastic may include polyethersulfone, polyacrylate, polyetherimide, polyethylene naphthalate, polyethylene terephthalate, polyphenylene sulfide, polyarylate, polyimide, polycarbonate, or cellulose acetate propionate.

The cover window 600 may include a flexible cover window. As an example, the cover window 600 may include polyimide and/or an ultra-thin glass.

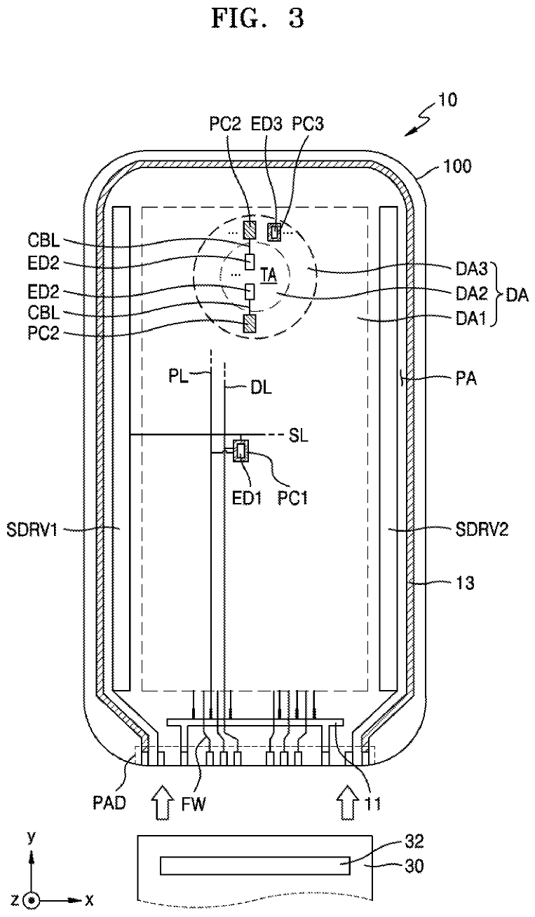

FIG. 3 is a schematic plan view of the display panel 10 according to an embodiment.

Referring to FIG. 3, the display panel 10 according to an embodiment may include the display area DA and the peripheral area PA. The light-emitting diodes may be arranged in the display area DA. The display area DA may correspond to an image surface of the display panel 10.

The display area DA may include the first display area DA1 and the second display area DA2, wherein the first display area DA1 occupies most of the area of the display area DA, and the second display area DA2 is surrounded by the first display area DA1 and includes the transmissive area TA. The light-emitting diodes arranged in the display area DA are electrically connected to the sub-pixel circuits, and the sub-pixel circuits electrically connected to the second light-emitting diodes ED2 arranged in the second display area DA2 are not arranged in the second display area DA to increase the area of the transmissive area TA. In an embodiment, the sub-pixel circuits electrically connected to the second light-emitting diodes ED2 may be arranged in a region between the first display area DA1 and the second display area DA2, for example, the third display area DA3.

In other words, light-emitting diodes are arranged in the first to third display areas DA1, DA2, and DA3. Sub-pixel circuits respectively electrically connected to the light-emitting diodes are arranged in the first and third display areas DA1 and DA3, but not arranged in the second display area DA2. As an example, sub-pixel circuits (referred to as first sub-pixel circuits PC1) respectively electrically connected to the first light-emitting diodes ED1 arranged in the first display area DA1 may be arranged in the first display area DA1. Some (e.g., second sub-pixel circuits PC2) of the sub-pixel circuits arranged in the third display area DA3 may be electrically connected to the second light-emitting diodes ED2 arranged in the second display area DA2, and others (e.g., third sub-pixel circuits PC3) of the sub-pixel circuits arranged in the third display area DA3 may be electrically connected to the third light-emitting diodes ED3 arranged in the third display area DA3. In the present specification, the first sub-pixel circuit PC1 denotes the sub-pixel circuit electrically connected to the first light-emitting diode ED1 arranged in the first display area DA1, the second sub-pixel circuit PC2 denotes the sub-pixel circuit electrically connected to the second light-emitting diode ED2 arranged in the second display area DA2, and the third sub-pixel circuit PC3 denotes the sub-pixel circuit electrically connected to the third light-emitting diode ED3 arranged in the third display area DA3.

The first light-emitting diode ED1 is arranged in the first display area DA1. Light emitted from the first light-emitting diode ED1 may correspond to light of the first sub-pixel P1 (see FIG. 1) described above with reference to FIG. 1, and the position of the first light-emitting diode ED1 may be the position of the first sub-pixel P1 (see FIG. 1). The first light-emitting diode ED1 may be configured to emit, for example, red, green, or blue light. The first sub-pixel circuit PC1 that drives the first light-emitting diode ED1 is arranged in the first display area DA1, and may be electrically connected to the first light-emitting diode ED1.

The first sub-pixel circuit PC1 is electrically connected to a scan line SL and a data line DL, wherein the scan line SL extends in a first direction (e.g., an x direction), and the data line DL extends in a second direction (e.g., a y direction). A first driving circuit SDRV1 and a second driving circuit SDRV2 configured to supply signals to each first sub-pixel circuit PC1 may be arranged in the peripheral area PA.

The first driving circuit SDRV1 may be configured to apply scan signals to the first sub-pixel circuit PC1 through the scan line SL. The second driving circuit SDRV2 may be positioned opposite the first driving circuit SDRV1 with the first display area DA1 therebetween. Some of the first sub-pixel circuits PC1 in the first display area DA1 may be electrically connected to the first driving circuit SDRV1, and the rest may be electrically connected to the second driving circuit SDRV2.

A pad PAD may be arranged on one side of the substrate 100. The pad PAD may be exposed by not being covered by an insulating layer, and connected to a circuit board 30. A control driver 32 may be disposed on the circuit board 30.

The control driver 32 may be configured to generate control signals transferred to the first driving circuit SDRV1 and the second driving circuit SDRV2. The control driver 32 may include a data driving circuit. The data driving circuit may be configured to generate data signals. Generated data signals may be transferred to the first sub-pixel circuits PC1 through a fan-out wiring FW and the data line DL, wherein the fan-out wiring FW is arranged in the peripheral area PA of the display panel 10, and the data line DL is connected to the fan-out wiring FW. In another embodiment, the data driving circuit may be arranged in the peripheral area PA of the substrate 100.

The second light-emitting diode ED2 is arranged in the second display area DA2. Light emitted from the second light-emitting diode ED2 may correspond to light of the second sub-pixel P2 (see FIG. 1) described above with reference to FIG. 1, and the position of the second light-emitting diode ED2 may be the position of the second sub-pixel P2 (see FIG. 1). The second light-emitting diode ED2 may be configured to emit, for example, red, green, or blue light.

The transmissive area TA may be located between the second light-emitting diodes ED2. In an embodiment, a region of the second display area DA2 in which the second light-emitting diodes ED2 are not arranged may correspond to the transmissive area TA. To increase the area of the transmissive area TA and improve a transmittance of the transmissive area TA, the second sub-pixel circuit PC2 configured to drive the second light-emitting diode ED2 may be arranged in the third display area DA3 outside the second display area DA2. Some of the second sub-pixel circuits PC2 may be arranged in a partial area of the third display area DA3 adjacent to the upper side of the second display area DA2, and others of the second sub-pixel circuits PC2 may be arranged in a partial region of the third display area DA3 adjacent to the lower side of the second display area DA2.

The second sub-pixel circuit PC2 in the third display area DA3 may be electrically connected to the second light-emitting diode ED2 in the second display area DA2 through the conductive bus line CBL. The second light-emitting diode ED2 may be electrically connected to the second sub-pixel circuit PC2 through the conductive bus line CBL extending in the second direction (e.g., the y direction).

The third light-emitting diode ED3 is arranged in the third display area DA3. Light emitted from the third light-emitting diode ED3 may correspond to light of the third sub-pixel P3 (see FIG. 1) described above with reference to FIG. 1, and the position of the third light-emitting diode ED3 may be the position of the third sub-pixel P3 (see FIG. 1). The third light-emitting diode ED3 may be configured to emit, for example, red, green, or blue light.

The third sub-pixel PC3 configured to drive the third light-emitting diode ED3 is arranged in the third display area DA3. The third sub-pixel circuit PC3 is electrically connected to the third light-emitting diode ED3 and may be configured to operate the third light-emitting diode ED3.

The second sub-pixel circuit PC2 and the third sub-pixel circuit PC3 may be electrically connected to the first driving circuit SDRV1 and/or the second driving circuit SDRV2. At least one of the second sub-pixel circuits PC2 and/or at least one of the third sub-pixel circuits PC3 may share the scan line with at least one of the first sub-pixel circuits PC1. At least one of the second sub-pixel circuits PC2 and/or at least one of the third sub-pixel circuits PC3 may share the data line with at least one of the first sub-pixel circuits PC1.

A driving voltage supply line 11 and a common voltage supply line 13 may be arranged in the peripheral area PA. The driving voltage supply line 11 may be configured to supply a driving voltage to a sub-pixel circuit, for example, each of the first to third sub-pixel circuits PC1, PC2, and PC3. The common voltage supply line 13 may be configured to apply a common voltage to a second electrode (a cathode) of the light-emitting diode, for example, the first to third light-emitting diodes ED1, ED2, and ED3.

The driving voltage supply line 11 may be arranged between the pad PAD and one side of the display area DA. The common voltage supply line 13 may have a loop shape having one open side and partially surround the display area DA in a plan view. The driving voltage supply line 11 may be electrically connected to a driving voltage line PL passing across the display area DA.

The first to third light-emitting diodes ED1, ED2, and ED3, the first to third sub-pixel circuits PC1, PC2, and PC3, the pad PAD, the first and second driving circuits SDRV1 and SDRV2, the driving voltage supply line 11, and the common voltage supply line 13 are arranged on the substrate 100. The shape of the display panel 10 shown in FIG. 3 may be substantially the same as the shape of the substrate 100. Accordingly, when the display panel 10 includes the display area DA and the peripheral area PA, it means that the substrate 100 includes the display area DA and the peripheral area PA.

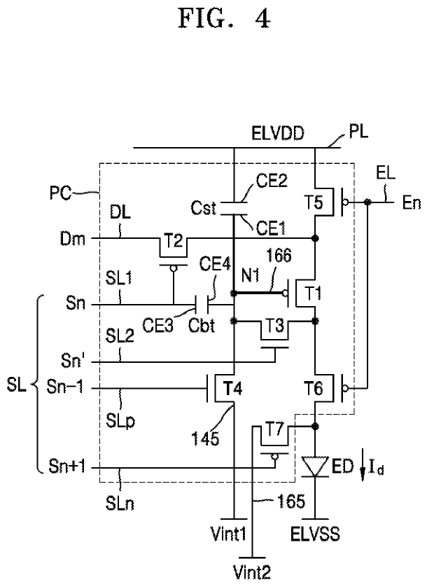

FIG. 4 is a schematic equivalent circuit diagram of a sub-pixel circuit electrically connected to a light-emitting diode of the display panel 10 according to an embodiment. The light-emitting diode ED of FIG. 4 may correspond to the first to third light-emitting diodes ED1, ED2, and ED3 described above with reference to FIG. 3. The sub-pixel circuit PC of FIG. 4 may correspond to the first to third sub-pixel circuits PC1, PC2, and PC3 described above with reference to FIG. 3. In other words, an equivalent circuit diagram of the first light-emitting diode ED1 (see FIG. 3) and the first sub-pixel circuit PC1, an equivalent circuit diagram of the second light-emitting diode ED2 (see FIG. 3) and the second sub-pixel circuit PC2, and an equivalent circuit diagram of the third light-emitting diode ED3 (see FIG. 3) and the third sub-pixel circuit PC3, may be the same. As described above, the light-emitting diode ED may include an organic light-emitting diode, an inorganic light-emitting diode, or a quantum-dot light-emitting diode.

The light-emitting diode ED may be electrically connected to the sub-pixel circuit PC. Referring to FIG. 4, the sub-pixel circuit PC may include first to seventh transistors T1, T2, T3, T4, T5, T6, and T7, a storage capacitor Cst, and a boost capacitor Cbt. In an embodiment, the sub-pixel circuit PC may not include the boost capacitor Cst. Hereinafter, for convenience of description, the case where the sub-pixel circuit PC includes the boost capacitor Cbt is described.

Some of the transistors T1, T2, T3, T4, T5, T6, and T7 may be n-channel metal oxide semiconductor (NMOS) field-effect transistors (n-channel MOSFET), and the rest may be p-channel metal oxide semiconductor (PMOS) field-effect transistors (p-channel MOSFET). As an example, as shown in FIG. 4, the third and fourth transistors T3 and T4 may be n-channel MOSFETs, and the rest may be p-channel MOSFETs. In another embodiment, the third, fourth, and seventh transistors T3, T4, and T7 may be n-channel MOSFETs, and the rest may be p-channel MOSFETs. Alternatively, only one transistor among the first to seventh transistors T1, T2, T3, T4, T5, T6, and T7 may be an n-channel MOSFET, and the rest may be p-channel MOSFETs.

The first to seventh transistors T1, T2, T3, T4, T5, T6, and T7, the storage capacitor Cst, and the boost capacitor Cbt may be connected to signal lines. The signal line may include the scan line SL, an emission control line EL, and the data line DL. The scan line SL may include a first scan line SL1 configured to transfer a first scan signal Sn, a second scan line SL2 configured to transfer a second scan signal Sn′, a previous scan line SLp configured to transfer a previous scan signal Sn−1, and a next scan line SLn configured to transfer a next scan signal Sn+1.

The driving voltage line PL is configured to transfer the driving voltage ELVDD to the first transistor T1, and first and second initialization voltage lines 145 and 165 may be configured to respectively transfer first and second initialization voltages Vint1 and Vint2.

The first transistor T1 may be a driving transistor. A first gate electrode (or a first control electrode) of the first transistor T1 may be connected to the storage capacitor Cst, a first electrode of the first transistor T1 may be electrically connected to the driving voltage line PL through the fifth transistor T5, and a second electrode of the first transistor T1 may be electrically connected to a first electrode (e.g., an anode) of the light-emitting diode ED through the sixth transistor T6. One of the first electrode and the second electrode of the first transistor T1 may be a source electrode, and the other may be a drain electrode. The first transistor T1 may be configured to supply a driving current Id to the light-emitting diode ED according to a switching operation of the second transistor T2.

The second transistor T2 may be a switching transistor. A second gate electrode (or a second control electrode) of the second transistor T2 is connected to the first scan line SL1, a first electrode of the second transistor T2 is connected to the data line DL, and a second electrode of the second transistor T2 is connected to the driving first electrode of the first transistor T1 and electrically connected to the driving voltage line PL through the fifth transistor T5. One of the first electrode and the second electrode of the second transistor T2 may be a source electrode, and the other may be a drain electrode. The second transistor T2 may be turned on according to a first scan signal Sn transferred through the first scan line SL and may perform a switching operation of transferring a data signal Dm to the first electrode of the first transistor T1, wherein the data signal Dm is transferred through the data line DL.

The third transistor T3 may be a compensation transistor configured to compensate for a threshold voltage of the first transistor T1. A third gate electrode (or a compensation control electrode) of the third transistor T3 is connected to the second scan line SL2. A first electrode of the third transistor T3 is connected to the lower electrode CE1 of the storage capacitor Cst through a node connection line 166, and connected to the first gate electrode of the first transistor T1. A first electrode of the third transistor T3 may be connected to the fourth transistor T4. A second electrode of the third transistor T3 is connected to the second electrode of the first transistor T1 and electrically connected to the first electrode (e.g., the anode) of the light-emitting diode ED through the sixth transistor T6. One of the first electrode and the second electrode of the third transistor T3 may be a source electrode, and the other may be a drain electrode.

The third transistor T3 may be turned on according to a second scan signal Sn′ (e.g., a compensation control signal) transferred through the second scan line SL2, and may diode-connect the first transistor T1 by electrically connecting the first gate electrode to the second electrode of the first transistor T1.

The fourth transistor T4 may be a first initialization transistor configured to initialize the first gate electrode of the first transistor T1. A fourth gate electrode (or a fourth control electrode) of the fourth transistor T4 is connected to the previous scan line SLp. A first electrode of the fourth transistor T4 is connected to a first initialization voltage line 145. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and the other may be a drain electrode. The fourth transistor T4 may be turned on according to a previous scan signal Sn−1 received through the previous scan line SL−1 and may perform an initialization operation of initializing the voltage of the first gate electrode of the first transistor T1 by transferring the first initialization voltage Vint1 to the first gate electrode of the driving transistor T1.

The fifth transistor T5 may be an operation control transistor. A fifth gate electrode (or a fifth control electrode) of the fifth transistor T5 is connected to the emission control line EL, a first electrode of the fifth transistor T5 is connected to the driving voltage line PL, and a second electrode of the fifth transistor T5 is connected to the first electrode of the first transistor T1 and the second electrode of the second transistor T2. One of the first electrode and the second electrode of the fifth transistor T5 may be a source electrode, and the other may be a drain electrode.

The sixth transistor T6 may be an emission control transistor. A sixth gate electrode (or a sixth control electrode) of the sixth transistor T6 is connected to the emission control line EL, a first electrode of the sixth transistor T6 is connected to the second electrode of the first transistor T1 and the second electrode of the third transistor T3, and a second electrode of the sixth transistor T6 is electrically connected to a second electrode of the seventh transistor T7 and the first electrode (e.g., the anode) of the light-emitting diode ED. One of the first electrode and the second electrode of the sixth transistor T6 may be a source electrode, and the other may be a drain electrode.

The fifth transistor T5 and the sixth transistor T6 may be simultaneously turned on according to an emission control signal En transferred through the emission control line EL, the driving voltage ELVDD is transferred to the light-emitting diode ED, and the driving current Id flows through the light-emitting diode ED.

The seventh transistor T7 may be a second initialization transistor configured to initialize the first electrode of the light-emitting diode ED. A seventh gate electrode (or a seventh control electrode) of the seventh transistor T7 is connected to the next scan line SLn. A first electrode of the seventh transistor T7 is connected to a second initialization voltage line 165. A second electrode of the seventh transistor T7 is connected to the second electrode of the sixth transistor T6 and the first electrode (e.g., the anode) of the light-emitting diode ED. The seventh transistor T7 may be turned on according to a next scan signal Sn+1 transferred through the next scan line SLn and may initialize the first electrode of the light-emitting diode ED by transferring the second initialization voltage Vint2 to the first electrode (e.g., the anode) of the light-emitting diode ED. Though it is shown in FIG. 4 that the seventh transistor T7 is connected to the next scan line SLn, the seventh transistor T7 may be connected to the previous scan line SLp.

The storage capacitor Cst includes a lower electrode CE1 and an upper electrode CE2. The lower electrode CE1 of the storage capacitor Cst is connected to the first gate electrode of the first transistor T1, and the upper electrode CE2 of the storage capacitor Cst is connected to the driving voltage line PL. The storage capacitor Cst may be configured to store charge corresponding to a difference between a voltage of the first gate electrode of the first transistor T1 and the driving voltage ELVDD.

The boost capacitor Cbt includes a third electrode CE3 and a fourth electrode CE4. The third electrode CE3 may be connected to the second gate electrode of the second transistor T2 and the first scan line SL1, and the fourth electrode CE4 may be connected to the first electrode of the third transistor T3 and the node connection line 166. The boost capacitor Cbt may raise the voltage of a first node N1 when a first scan signal Sn supplied to the first scan line SL1 is turned off. When the voltage of the first node N1 is raised, a black grayscale may be clearly expressed.

The first node N1 may be a region where the first gate electrode of the first transistor T1, the first electrode of the third transistor T3, the second electrode of the fourth transistor T4, and the fourth electrode CE4 of the boost capacitor Cbt are connected to each other.

In an embodiment, it is described in FIG. 4 that the third and fourth transistors T3 and T4 are n-channel MOSFETs, and the first, second, fifth to seventh transistors T1, T2, T5, T6, and T7 are p-channel MOSFETs. The first transistor T1 directly influencing the brightness of the display apparatus may be configured to include a semiconductor layer including polycrystalline silicon having high reliability, and thus, a high-resolution display apparatus may be implemented through this configuration.

Though it is described in FIG. 4 that the third and fourth transistors T3 and T4 are n-channel MOSFETs, the first to seventh transistors T1, T2, T3, T4, T5, T6, and T7 may be p-channel MOSFETs in another embodiment. In this case, the second and third transistors T2 and T3 may be electrically connected to the same scan line. In an embodiment, the fourth and seventh transistors T4 and T7 may be electrically connected to the same scan line. In an embodiment, the fourth and seventh transistors T4 and T7 may be electrically connected to the same initialization voltage line.

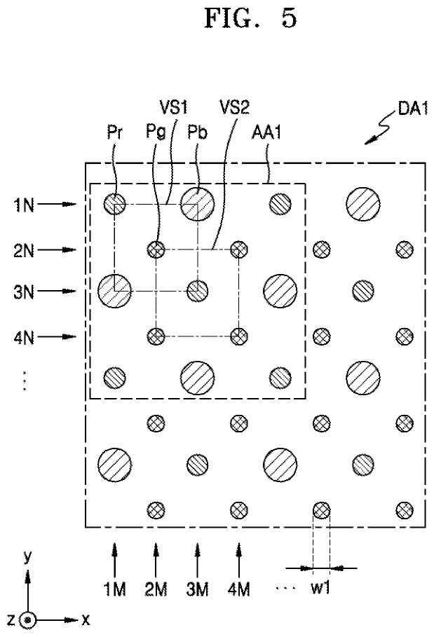

FIG. 5 is a plan view of first sub-pixels arranged in a first display area of a display panel according to an embodiment.

Referring to FIG. 5, the first sub-pixels in the first display area DA1 may include sub-pixels of different colors. As an example, the first sub-pixels may include a sub-pixel of a first color, a sub-pixel of a second color, and a sub-pixel of a third color. In other words, the sub-pixels of the first color, the sub-pixels of the second color, and the sub-pixels of the third color may be arranged in the first display area DA1. Hereinafter, for convenience of description, the case where the sub-pixel of the first color is a green sub-pixel Pg, the sub-pixel of the second color is a red sub-pixel Pr, and the sub-pixel of the third color is a green sub-pixel Pb is described.

In an embodiment, the red sub-pixel Pr, the green sub-pixel Pg, and the blue sub-pixel Pb may be arranged in a diamond PenTile™ in the display area DA1. In FIG. 5, 1N, 2N, 3N, 4N, . . . represent rows of the sub-pixels, and 1M, 2M, 3M, 4M, . . . represent columns of the sub-pixels.

As an example, a plurality of red sub-pixels Pr and a plurality of blue sub-pixels Pb are alternately arranged on a first row 1N, a plurality of green sub-pixels Pg are arranged at a preset interval on an adjacent second row 2N, and a plurality of blue sub-pixels Pb and a plurality of red sub-pixels Pr are alternately arranged on an adjacent third row 3N, and a plurality of green sub-pixels Pg are arranged at a preset interval on an adjacent fourth row 4N. Such a pixel configuration is repeated. In an embodiment, the size (or the width) of the blue sub-pixel Pb and the red sub-pixel Pr may be greater than the size (or the width) of the green sub-pixel Pg. The size (or the width) of the blue sub-pixel Pb may be the same as or different from the size (or the width) of the red sub-pixel Pr. As an example, the size (or the width) of the blue sub-pixel Pb may be greater than the size (or the width) of the red sub-pixel Pr.

The plurality of red sub-pixels Pr and the plurality of blue sub-pixels Pb on the first row 1N, and a plurality of green sub-pixels Pg on the second row 2N are alternately arranged with each other. Accordingly, the red sub-pixels Pr and the blue sub-pixels Pb are alternately arranged on a first column 1M, the plurality of green sub-pixels Pg are apart from each other at a preset interval on an adjacent second column 2M, and the blue sub-pixels Pb and the red sub-pixels Pr are alternately arranged on an adjacent third column 3M, and the plurality of green sub-pixels Pg are apart from each other at a preset interval on an adjacent fourth column 4M. Such a pixel configuration is repeated.

Such a pixel configuration structure may be expressed, in which red sub-pixels Pr are respectively arranged on first and third vertexes located in a first diagonal direction among the vertexes of a first virtual quadrangle VS1 with a green sub-pixel Pg centered at the center of the quadrangle, and blue sub-pixels are respectively arranged on second and fourth vertexes, which are the rest of the vertexes.

Such a pixel configuration structure may be expressed, in which green sub-pixels Pg are respectively arranged on the vertexes of a second virtual quadrangle VS2 with a red sub-pixel Pr or a blue sub-pixel Pb centered at the center of the quadrangle.

The first and second virtual quadrangles VS1 and VS2 are rectangles in the Euclidean plane geometry, and rectangles in which two sides connected to each other are different in length or rectangles (that is, squares) in which four sides are equal in length. In another embodiment, the first and second virtual quadrangles VS1 and VS2 may be rhombuses.

This pixel arrangement structure is referred to as a diamond-type PenTile™. By applying rendering, in which a color of a sub-pixel is represented by sharing the colors of its adjacent pixels, a high resolution may be obtained via a small number of sub-pixels.

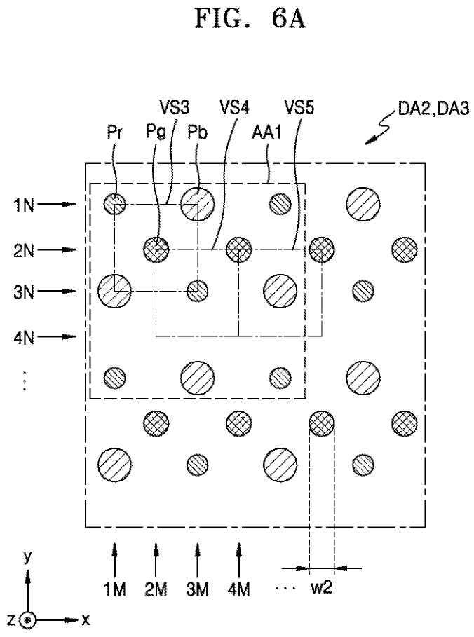

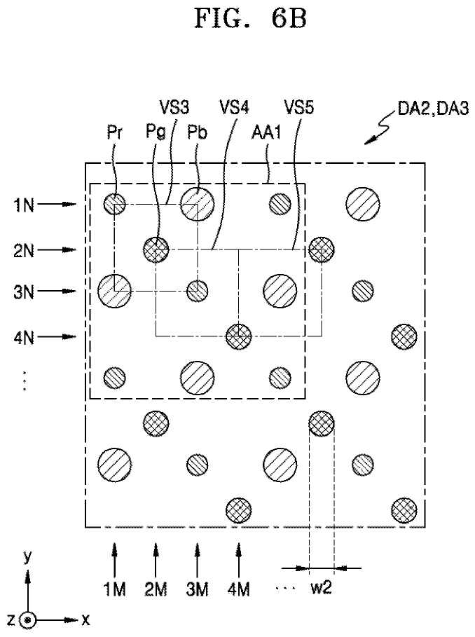

FIG. 6A is a plan view of second sub-pixels and third sub-pixels arranged in the second display area DA2 and the third display area DA3 of the display panel 10 according to an embodiment.

Referring to FIG. 6A, the second and third sub-pixels respectively arranged in the second and third display areas DA2 and DA3 may include sub-pixels of different colors. As an example, the second and third sub-pixels may include a sub-pixel of the first color, a sub-pixel of the second color, and a sub-pixel of the third color. In other words, sub-pixels of the first color, sub-pixels of the second color, and sub-pixels of the third color may be arranged in each of the second and third display areas DA2 and DA3. Hereinafter, for convenience of description, the case where the sub-pixel of the first color is the green sub-pixel Pg, the sub-pixel of the second color is the red sub-pixel Pr, and the sub-pixel of the third color is the green sub-pixel Pb is described. A configuration of the sub-pixels shown in FIG. 6A may be a configuration of the sub-pixels arranged in the second display area DA2 and a configuration of the sub-pixels arranged in the third display area DA3. In other words, the configuration of the green, red, and blue sub-pixels Pg, Pr, and Pb in the second display area DA2 may be the same as the configuration of the green, red, and blue sub-pixels Pg, Pr, and Pb in the third display area DA3.

In each of the second and third display areas DA2 and DA3, the red sub-pixel Pr, the green sub-pixel Pg, and the blue sub-pixel Pb may be arranged along a row and a column. In FIG. 6A, 1N, 2N, 3N, 4N, . . . represent rows of the sub-pixels, and 1M, 2M, 3M, 4M, . . . represent columns of the sub-pixels.

A plurality of red sub-pixels Pr and a plurality of blue sub-pixels Pb are alternately arranged in a first row 1N, a plurality of green sub-pixels Pg are arranged at a preset interval in an adjacent second row 2N, a plurality of blue sub-pixels Pb and a plurality of red sub-pixels Pr are alternately arranged in an adjacent third row 3N, and sub-pixels may not be arranged in an adjacent fourth row 4N.

The plurality of red sub-pixels Pr and the plurality of blue sub-pixels Pb on the first row 1N, and a plurality of green sub-pixels Pg on the second row 2N are alternately arranged with each other. Accordingly, the red sub-pixels Pr and the blue sub-pixels Pb are alternately arranged in a first column 1M, the plurality of green sub-pixels Pg are apart from each other at a preset interval in an adjacent second column 2M, and the blue sub-pixels Pb and the red sub-pixels Pr are alternately arranged in an adjacent third column 3M, and a sub-pixel circuit is not arranged in an adjacent fourth column 4M. Such a sub-pixel column arrangement is repeated.

Such a sub-pixel configuration structure of FIG. 6A may be differently expressed, in which red sub-pixels Pr are respectively arranged on first and third vertexes located in a first diagonal direction among the vertexes of a third virtual quadrangle VS3 with a green sub-pixel Pg centered at the center of the quadrangle, and blue sub-pixels are respectively arranged on second and fourth vertexes located in a second diagonal direction crossing the first diagonal direction.

Such a sub-pixel configuration structure of FIG. 6A may be expressed, in which green sub-pixels Pg are respectively arranged on two vertexes of four vertexes of a fourth virtual quadrangle VS4 with a red sub-pixel Pr or a blue sub-pixel Pb centered at the center of the quadrangle. As an example, as shown in FIG. 6A, the green sub-pixels Pg may be respectively arranged on two vertexes adjacent in a row direction (e.g., the x direction) among the four vertexes of the fourth virtual quadrangle VS4, and the sub-pixels may not be arranged on two remaining vertexes. In other words, the green sub-pixels Pg may be respectively arranged on two vertexes adjacent in a row direction (e.g., the x direction) among the four vertexes of a fifth virtual quadrangle VS5 with the blue sub-pixel Pb centered at the center of the fifth virtual quadrangle VS5, and the sub-pixels may not be arranged on two remaining vertexes.

The third and fifth virtual quadrangles VS3, VS4, and VS5 are rectangles in the Euclidean plane geometry, and rectangles in which two sides connected to each other are different in length, rectangles (that is, squares) in which four sides are equal in length, or rhombuses. Each of the third to fifth virtual quadrangles VS3, VS4, and VS5 may have substantially the same size (or the area) of the first and second virtual quadrangles VS1 and VS2.

Referring to FIGS. 5 and 6A, the number of sub-pixels positioned in the first display area DA1 and the number of sub-pixel circuits positioned in the second display area DA2 may be different from each other per the same area. Likewise, the number of sub-pixels positioned in the first display area DA1 and the number of sub-pixel circuits positioned in the third display area DA3 may be different from each other per the same area.

As an example, the number of sub-pixels arranged in an arbitrary area AA1 having a first area (first size) in the first display area DA1 shown in FIG. 5 may be greater than the number of sub-pixels arranged in an arbitrary area AA1 having the first area (first size) in the second display area DA2 shown in FIG. 6A. Likewise, the number of sub-pixels arranged in an arbitrary area AA1 having a first area (first size) in the first display area DA1 shown in FIG. 5 may be greater than the number of sub-pixels arranged in an arbitrary area AA1 having the first area (first size) in the third display area DA3 shown in FIG. 6A.

Because the number of sub-pixels arranged in the second display area DA2 is less than the number of sub-pixels arranged in the first display area DA1 per the same area, a portion of the transmissive area in the second display area DA2 may be relatively increased. In contrast, because the number of sub-pixels arranged in the second display area DA2 is less than the number of sub-pixels arranged in the first display area DA1 per the same area, the resolution of the first display area DA1 may be different from the resolution of the second display area DA2. In contrast, according to an embodiment, because the size (or the width) of the green sub-pixel Pg arranged in the second display area DA2 is made greater than the size (or the width) of the green sub-pixel Pg arranged in the first display area DA1, the above issue may be prevented or reduced. As an example, a width w2 (see FIG. 6A) of the green sub-pixel Pg in the second display area DA2 may be greater than a width w1 (see FIG. 5) of the green sub-pixel Pg in the first display area DA1. The width w2 (see FIG. 6A) of the green sub-pixel Pg in the second display area DA2 may be less than about twice the width w1 (see FIG. 5) of the green sub-pixel Pg in the first display area DA1. As an example, the width w2 (see FIG. 6A) of the green sub-pixel Pg in the second display area DA2 may be about 21 μm and the width w1 (see FIG. 5) of the green sub-pixel Pg in the first display area DA1 may be about 17 μm.

Referring to FIGS. 5 and 6A, the size (or the width) of the blue sub-pixel Pb in the first display area DA1 may be the same as the size (or the width) of the blue sub-pixel Pb in the second display area DA2. The size (or the width) of the red sub-pixel Pr in the first display area DA1 may be the same as the size (or the width) of the red sub-pixel Pr in the second display area DA2. The size (or the width w2) (see FIG. 6A) of the green sub-pixel Pg in the second display area DA2 may be greater than the size (or the width w1) (see FIG. 5) of the green sub-pixel Pg in the first display area DA1, and a deviation in the resolution and/or the brightness may be reduced through the above structure.

In an embodiment, the size (or the width) of the red sub-pixel Pr in the first display area DA1 may be greater than the size (or the width) of the green sub-pixel Pg in the first display area DA1. In contrast, the size (or the width) of the red sub-pixel Pr in the second display area DA2 may be less than the size (or the width) of the green sub-pixel Pg in the second display area DA2.

FIG. 6B is a plan view of a configuration of the second and third sub-pixels arranged in the second and third display areas DA2 and DA3 of the display panel 10 according to an embodiment.

Referring to FIG. 6B, the second and third sub-pixels respectively arranged in the second and third display areas DA2 and DA3 may include sub-pixels of different colors. As an example, as described above with reference to FIG. 6A, the sub-pixels of the first color (e.g., green sub-pixels Pg), the sub-pixels of the second color (e.g., red sub-pixels Pr), and the sub-pixels of the third color (e.g., blue sub-pixels Pb) may be arranged. A configuration of the sub-pixels shown in FIG. 6B may be a configuration of the sub-pixels arranged in the second display area DA2 and a configuration of the sub-pixels arranged in the third display area DA3. In other words, the configuration of the green, red, and blue sub-pixels Pg, Pr, and Pb in the second display area DA2 may be the same as the configuration of the green, red, and blue sub-pixels Pg, Pr, and Pb in the third display area DA3.

In each of the second and third display areas DA2 and DA3, the red sub-pixel Pr, the green sub-pixel Pg, and the blue sub-pixel Pb may be arranged along a row and a column. In FIG. 6A, 1N, 2N, 3N, 4N, . . . represent rows of the sub-pixels, and 1M, 2M, 3M, 4M, . . . represent columns of the sub-pixels.

A plurality of red sub-pixels Pr and a plurality of blue sub-pixels Pb are alternately arranged in a first row 1N, a plurality of green sub-pixels Pg are arranged at a preset interval in an adjacent second row 2N, and a plurality of blue sub-pixels Pb and a plurality of red sub-pixels Pr are alternately arranged in an adjacent third row 3N, and a plurality of green sub-pixels Pg are arranged at a preset interval in an adjacent fourth row 4N. A separation distance between two adjacent green sub-pixels Pg in the second row 2N and/or the fourth row 4N may be greater than a separation distance between a red sub-pixel Pr and a blue sub-pixel Pb in the first row 1N and/or the third row 3N.

The plurality of red sub-pixels Pr and the plurality of blue sub-pixels Pb on the first row 1N, and a plurality of green sub-pixels Pg on the second row 2N are alternately arranged with each other. Accordingly, the red sub-pixels Pr and the blue sub-pixels Pb are alternately arranged in a first column 1M, the plurality of green sub-pixels Pg are apart from each other at a preset interval in an adjacent second column 2M, and the blue sub-pixels Pb and the red sub-pixels Pr are alternately arranged in an adjacent third column 3M, and the plurality of green sub-pixels Pg are apart from each other at a preset interval in an adjacent fourth column 4M. A separation distance between two adjacent green sub-pixels Pg in the second column 2M and/or the fourth column 4M may be greater than a separation distance between a red sub-pixel Pr and a blue sub-pixel Pb in the first column 1M and/or the third column 3M.

Such a sub-pixel configuration structure of FIG. 6B may be differently expressed, in which red sub-pixels Pr are respectively arranged on first and third vertexes located in a first diagonal direction among the vertexes of a third virtual quadrangle VS3 with a green sub-pixel Pg centered at the center of the quadrangle, and blue sub-pixels are respectively arranged on second and fourth vertexes located in a second diagonal direction crossing the first diagonal direction.

Such a sub-pixel configuration structure of FIG. 6B may be differently expressed, in which green sub-pixels Pg are respectively arranged on two vertexes of four vertexes of a fourth virtual quadrangle VS4 with a red sub-pixel Pr or a blue sub-pixel Pb centered at the center of the quadrangle. As an example, as shown in FIG. 6B, the green sub-pixels Pg may be respectively arranged on two vertexes (e.g., first and third vertexes) arranged in a first diagonal direction among the four vertexes of the fourth virtual quadrangle VS4 with the red sub-pixel Pr centered, and the sub-pixels are not arranged the two remaining vertexes. In other words, the green sub-pixels Pg may be respectively arranged on two vertexes (e.g., second and fourth vertexes) arranged in a second diagonal direction among the four vertexes of the fifth virtual quadrangle VS5 with the blue sub-pixel Pb centered, and the sub-pixels are not arranged the two remaining vertexes.

The third and fifth virtual quadrangles VS3, VS4, and VS5 are rectangles in the Euclidean plane geometry, and rectangles in which two sides connected to each other are different in length, rectangles (that is, squares) in which four sides are equal in length, or rhombuses. Each of the third to fifth virtual quadrangles VS3, VS4, and VS5 may have substantially the same size (or the area) of the first and second virtual quadrangles VS1 and VS2.

Referring to FIGS. 5 and 6B, the number of sub-pixels positioned in the first display area DA1 and the number of sub-pixel circuits positioned in the second display area DA2 may be different from each other per the same area. Likewise, the number of sub-pixels positioned in the first display area DA1 and the number of sub-pixel circuits positioned in the third display area DA3 may be different from each other per the same area.

As an example, the number of sub-pixels arranged in an arbitrary area AA1 having a first area in the first display area DA1 shown in FIG. 5 may be greater than the number of sub-pixels arranged in an arbitrary area AA1 having a first area in the second display area DA2 shown in FIG. 6B. Likewise, the number of sub-pixels arranged in an arbitrary area AA1 having a first area in the first display area DA1 shown in FIG. 5 may be greater than the number of sub-pixels arranged in an arbitrary area AA1 having a first area in the third display area DA3 shown in FIG. 6B.

Because the number of sub-pixels arranged in the second display area DA2 is less than the number of sub-pixels arranged in the first display area DA1 per the same area, a portion of the transmissive area in the second display area DA2 may be relatively increased. In contrast, because the number of sub-pixels arranged in the second display area DA2 is less than the number of sub-pixels arranged in the first display area DA1 per the same area, the resolution of the first display area DA1 may be different from the resolution of the second display area DA2. In contrast, according to an embodiment, because the size (or the width) of the green sub-pixel Pg arranged in the second display area DA2 is made greater than the size (or the width) of the green sub-pixel Pg arranged in the first display area DA1, the above issue may be prevented or reduced. As an example, a width w2 (see FIG. 6B) of the green sub-pixel Pg in the second display area DA2 may be greater than a width w1 (see FIG. 5) of the green sub-pixel Pg in the first display area DA1.

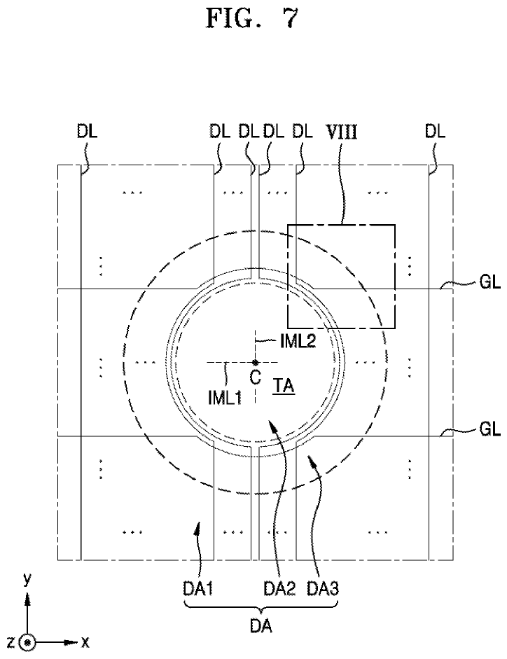

FIG. 7 is a plan view of a portion of the display panel 10 according to an embodiment.

For convenience of description, FIG. 7 shows signal lines, for example, the data lines DL and the gate lines GL, passing across the display area DA.

Referring to FIG. 7, the gate lines GL may each extend in the first direction (e.g., the x direction). The gate lines GL may be bent or curved along the outer side of the second display area DA2 in the third display area DA3. As an example, one of the gate lines GL may be bent or curved along the upper side of the second display area DA2 in the third display area DA3, and another of the gate lines GL may be bent or curved along the lower side of the second display area DA2 in the third display area DA3. As an example, one of the gate lines GL curved along the upper side of the second display area DA2, and the other of the gate lines GL curved along the lower side of the second display area DA2, may be symmetrical to a first virtual line IML1 passing through the center C of the second display area DA2.

In FIG. 7, the gate line GL may be the scan line SL and/or the emission control line EL connected to the sub-pixel circuit PC (see FIG. 4) described above with reference to FIG. 4. As an example, the gate line GL may include the first gate line SL1 (see FIG. 4), the second gate line SL2 (see FIG. 4), the previous scan line SLp (see FIG. 4), the next scan line SLn (see FIG. 4), and/or the emission control line EL (see FIG. 4). In other words, the first gate line SL1 (see FIG. 4), the second gate line SL2 (see FIG. 4), the previous scan line SLp (see FIG. 4), the next scan line SLn (see FIG. 4), and/or the emission control line EL (see FIG. 4) electrically connected to the sub-pixel circuits arranged in the third display area DA3 may be bent or curved in the third display area DA3 to partially surround the second display area DA2.

The data lines DL may extend entirely in the second direction (e.g., the y direction). Some of the first display areas DA1 may be bent or curved along the outer side of the second display area DA2 in the third display area DA3. As an example, one of the data lines DL may be bent or curved along the left side of the second display area DA2 in the third display area DA3, and another of the data lines DL may be bent or curved along the right side of the second display area DA2 in the third display area DA3. One of the data lines DL curved along the left side of the second display area DA2, and another of the data lines DL curved along the right side of the second display area DA2 may be symmetrical to each other with respect to a second virtual line IML2.

As described above, the data line DL and the gate line GL do not pass across the second display area DA2, and thus, the transmissive area TA may be sufficiently secured.

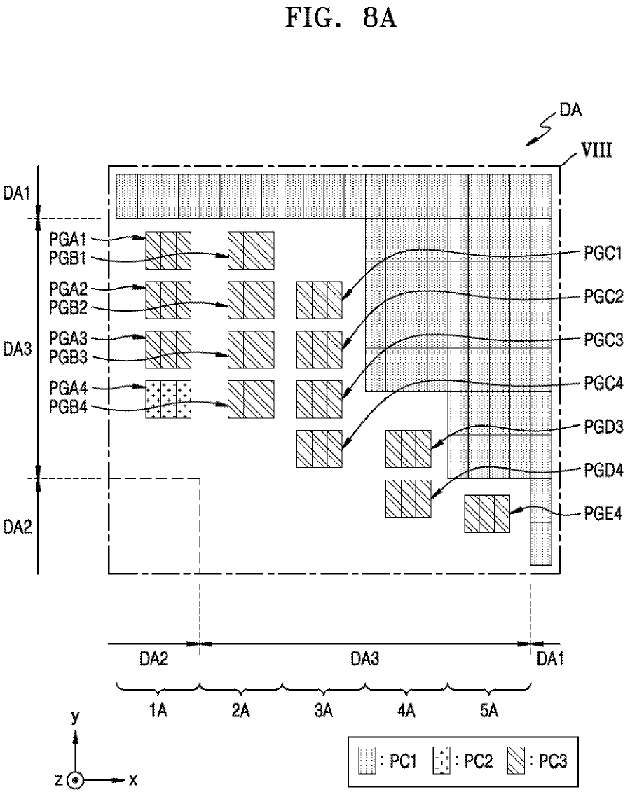

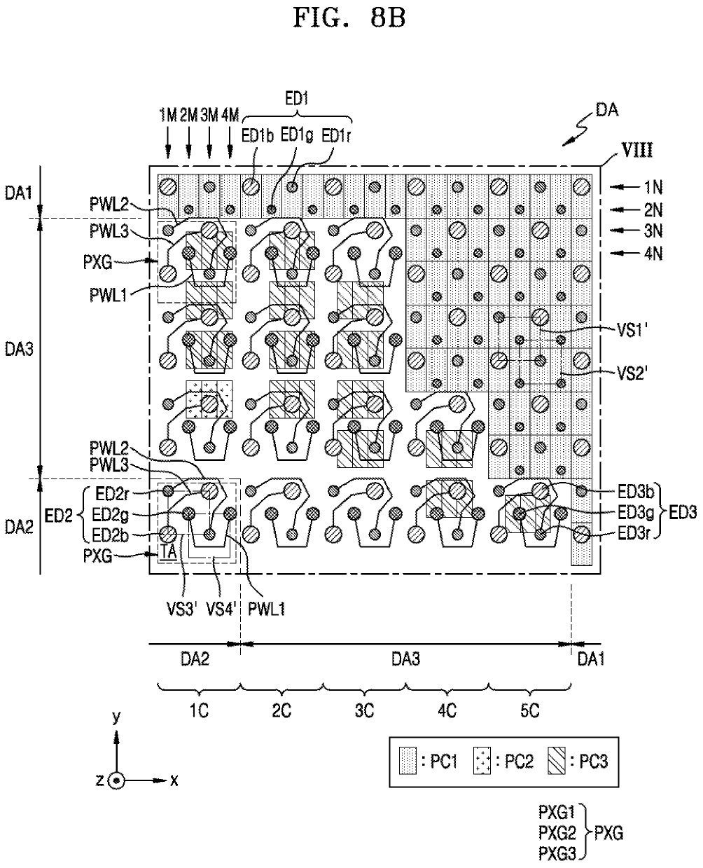

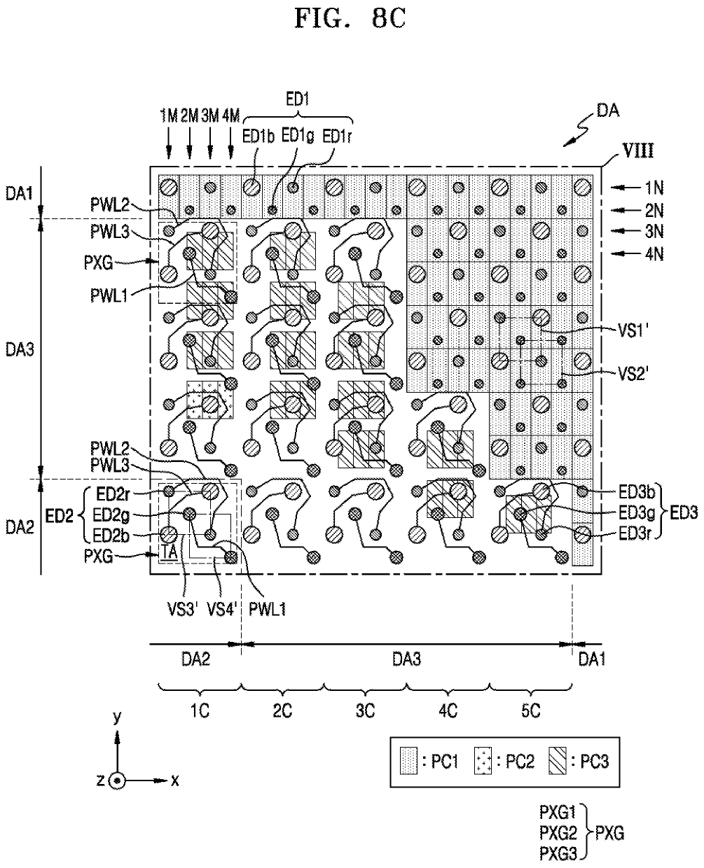

FIG. 8A is a view of sub-pixel circuits located in a region VIII of FIG. 7 as a portion of the display panel 10 according to an embodiment. FIG. 8B is a view of light-emitting diodes on sub-pixel circuits located in the region VIII of FIG. 7 as a portion of the display panel 10 according to an embodiment. FIG. 8C is a view of light-emitting diodes on sub-pixel circuits located in the region VIII of FIG. 7 as a portion of the display panel 10 according to another embodiment. For convenience of description, FIG. 8A shows the sub-pixel circuits, FIGS. 8B and 8C show the light-emitting diodes electrically connected to the sub-pixel circuits in FIG. 8A.

Referring to FIG. 8A, the sub-pixel circuits are arranged in the first display area DA1 and the third display area DA3 but not arranged in the second display area DA2 of the display area DA.

The sub-pixel circuits, for example, the first sub-pixel circuits PC1 arranged in the first display area DA1 may be arranged to form a row and a column. The first sub-pixel circuits PC1 may be arranged at a preset interval in the first direction (e.g., the x direction) and the second direction (e.g., the y direction). In an embodiment, the first sub-pixel circuits PC1 adjacent to the third display area DA3, may be arranged to have a stepwise configuration in a plan view.

The sub-pixel circuits arranged in the third display area DA3 may be also arranged to form rows and columns. The sub-pixel circuits, for example, the second sub-pixel circuits PC2 and the third sub-pixel circuits PC3 arranged in the third display area DA3, may be arranged to form row and columns in the third display area DA3. The second sub-pixel circuits PC2 and the third sub-pixel circuits PC3 may form different rows and columns from rows and columns of the first sub-pixel circuits PC1 arranged in the first display area DA1. As an example, three second sub-pixel circuits PC2 may form one sub-pixel circuit group, and three third sub-pixel circuits PC3 may form one sub-pixel circuit group.

The sub-pixel circuit groups may be arranged to be apart from each other in the first direction (e.g., the x direction) and/or the second direction (e.g., the y direction) in the third display area DA3. With regard to this, FIG. 8A shows sub-pixel circuit groups PGA1, PGA2, PGA3, and PGA4 arranged in a first column 1A in the second direction (e.g., they direction), sub-pixel circuit groups PGB1, PGB2, PGB3, and PGB4 arranged in a second column 2A, sub-pixel circuit groups PGC1, PGC2, PGC3 and PGC4 arranged in a third column 3A, and sub-pixel circuit groups PGD3 and PGD4 arranged in a fourth column 4A, and a sub-pixel circuit group PGE4 arranged in a fifth column 5A.

The sub-pixel circuit groups arranged in the third display area DA3 may be apart from each other in the first direction (e.g., the x direction, a row direction of the sub-pixel circuit group). The sub-pixel circuit groups arranged in the third display area DA3 may be apart from each other in the second direction (e.g., the y direction, a column direction of the sub-pixel circuit group). As an example, it is shown in FIG. 8A that the sub-pixel circuit groups arranged in the same column are apart from each other in the second direction (e.g., the y direction, a column direction of the sub-pixel circuit group), the embodiment is not limited thereto. In another embodiment, the sub-pixel circuit groups arranged in the same column may not be apart from each other in the second direction (e.g., the y direction, a column direction of the sub-pixel circuit group).

The sub-pixel circuits arranged in the first and third display areas DA1 and DA3 may be configured to drive the light-emitting diodes arranged in the first to third display areas DA1, DA2, and DA3.

Referring to FIGS. 8B and 8C, the light-emitting diodes may include the first light-emitting diodes ED1 arranged in the first display area DA1, the second light-emitting diodes ED2 arranged in the second display area DA2, and the third light-emitting diodes ED3 arranged in the third display area DA3.

The first light-emitting diodes ED1 may include a first red light-emitting diodes ED1r, a first green light-emitting diodes ED1g, and a first blue light-emitting diodes ED1b. The second light-emitting diodes ED2 may include a second red light-emitting diodes ED2r, a second green light-emitting diodes ED2g, and a second blue light-emitting diodes ED2b. The third light-emitting diodes ED3 may include a third red light-emitting diodes ED3r, a third green light-emitting diodes ED3g, and a third blue light-emitting diodes ED3b.

In the first display area DA1, a configuration of the first red light-emitting diodes ED1r, the first green light-emitting diodes ED1g, and the first blue light-emitting diodes ED1b may be substantially the same as a configuration of the red, green, and blue sub-pixels described above with reference to FIG. 5. As an example, in the first display area DA1, the first red light-emitting diodes ED1r and the first blue light-emitting diodes ED1b may be alternately arranged in the first row 1N, the first green light-emitting diodes ED1g may be apart from each other at a preset interval in the adjacent second row 2N, the first blue light-emitting diodes ED1b and the first red light-emitting diodes ED1r may be alternately arranged in the adjacent third row 3N, and the first green light-emitting diodes ED1g may be apart from each other at a preset interval in the adjacent fourth row 4N.

The first red light-emitting diodes ED1r and the first blue light-emitting diodes ED1b arranged in the first row 1N, and the first green light-emitting diodes ED1g arranged in the second row 2N may be alternately arranged. Accordingly, in the display area DA, the first red light-emitting diodes ED1r and the first blue light-emitting diodes ED1b are arranged in turns in the first column 1M, the plurality of green light-emitting diodes are apart from each other in an adjacent second column 2M, the blue light-emitting diodes and the red light-emitting diodes are arranged in turns in an adjacent third column 3M, and the plurality of green light-emitting diodes are apart from each other in an adjacent fourth column 4M. Such a pixel configuration is repeated.

The configuration of the first light-emitting diodes is described below in other words. As an example, first red light-emitting diodes ED1r may be respectively arranged on first and third vertexes located in a diagonal direction among the vertexes of a first virtual quadrangle VS1′ with a green light-emitting diode ED1g centered at the center of the quadrangle, and first blue light-emitting diodes may be respectively arranged on second and fourth vertexes, which are the rest of the vertexes, wherein the first green light-emitting diode ED1g is arranged in the first display area DA1. The configuration structure of the first light-emitting diodes ED1 may be expressed, in which the first green light-emitting diodes ED1g are respectively arranged on four vertexes of a second virtual quadrangle VS2′ with the first red light-emitting diode ED1r or the first blue light-emitting diode ED1b centered at the center of the quadrangle.

In the second display area DA2, a configuration of the second red light-emitting diodes ED2r, the second green light-emitting diodes ED2g, and the second blue light-emitting diodes ED2b may be substantially the same as a configuration of the red, green, and blue sub-pixels described above with reference to FIG. 6A. Alternatively, in the second display area DA2, a configuration of the second red light-emitting diodes ED2r, the second green light-emitting diodes ED2g, and the second blue light-emitting diodes ED2b may be substantially the same as a configuration of the red, green, and blue sub-pixels described above with reference to FIG. 6B.

As an example, second red light-emitting diodes ED2r may be respectively arranged on first and third vertexes located in a diagonal direction among the vertexes of a third virtual quadrangle VS3′ with a second green light-emitting diode ED2g centered at the center of the quadrangle, and second blue light-emitting diodes ED2b may be respectively arranged on second and fourth vertexes, which are the rest of the vertexes, wherein the second green light-emitting diode ED2g is arranged in the second display area DA2. The configuration structure of the second light-emitting diodes ED2 may be differently expressed, in which the second green light-emitting diodes ED2g are respectively arranged on two vertexes among four vertexes of a fourth virtual quadrangle VS4′ with the second red light-emitting diode ED2r or the second blue light-emitting diode ED2b centered at the center of the quadrangle. As an example, as shown in FIG. 8B, the second green light-emitting diodes ED2g may be respectively arranged on two vertexes adjacent in a row direction (e.g., the x direction) among the four vertexes of the fourth virtual quadrangle VS4′. Alternatively, as shown in FIG. 8C, the second green light-emitting diodes ED2g may be respectively arranged on two vertexes adjacent in a first diagonal direction (or a second diagonal direction) among the four vertexes of the fourth virtual quadrangle VS4′.

Similarly, in the third display area DA3, a configuration of the third red light-emitting diodes ED3r, the third green light-emitting diodes ED3g, and the third blue light-emitting diodes ED3b may be substantially the same as a configuration of the red, green, and blue sub-pixels described above with reference to FIG. 6A. Alternatively, in the third display area DA3, a configuration of the third red light-emitting diodes ED3r, the third green light-emitting diodes ED3g, and the third blue light-emitting diodes ED3b may be substantially the same as a configuration of the red, green, and blue sub-pixels described above with reference to FIG. 6B.

The configuration of the third light-emitting diodes ED3 arranged in the third display area DA3 is the same as the configuration of the second light-emitting diodes ED2. As an example, third red light-emitting diodes ED3r may be respectively arranged on first and third vertexes located in a first diagonal direction among the vertexes of a virtual quadrangle with a third green light-emitting diode ED3g centered at the center of the quadrangle, and third blue light-emitting diodes ED3b may be respectively arranged on second and fourth vertexes, which are the rest of the vertexes, wherein the third green light-emitting diode ED3g is arranged in the third display area DA3. The configuration structure of the third light-emitting diodes ED3 may be differently expressed, in which the third green light-emitting diodes ED3g are respectively arranged on two vertexes among four vertexes of a virtual quadrangle with the third red light-emitting diode ED3r or the third blue light-emitting diode ED3b centered at the center of the quadrangle.

The first light-emitting diodes ED1 in the first display area DA1 may be electrically connected to the first sub-pixel circuits PC1 in the first display area DA1. As an example, one first light-emitting diodes ED1 may correspond to one first sub-pixel circuit PC1 (one-to-one correspondence). A first red light-emitting diode ED1r may be electrically connected to a corresponding first sub-pixel circuit PC1, a first green light-emitting diode ED1g may be electrically connected to a corresponding first sub-pixel circuit PC1, and a first blue light-emitting diode ED1b may be electrically connected to a corresponding first sub-pixel circuit PC1.

The second and third light-emitting diodes ED2 and ED3 respectively arranged in the second display area DA2 and the third display area DA3, may be electrically connected to the sub-pixel circuits arranged in the third display area DA3. In FIGS. 8B and 8C, for convenience of description, the light-emitting diodes (e.g., the light-emitting diodes arranged in the second display area DA2 and the third display area DA3) electrically connected to the sub-pixel circuit groups in the third display area DA3, are referred to as a light-emitting diode group PXG. Each light-emitting diode group PXG may include two red light-emitting diodes, two blue light-emitting diodes, and two green light-emitting diodes. As an example, each light-emitting diode group PXG arranged in the second display area DA2, may include two second red light-emitting diodes ED2r, two second green light-emitting diodes ED2g, and two second blue light-emitting diodes ED2b. As an example, each light-emitting diode group PXG arranged in the third display area DA3, may include two third red light-emitting diodes ED3r, two third green light-emitting diodes ED3g, and two third blue light-emitting diodes ED3b. In FIGS. 8B and 8C, reference numerals 1C, 2C, 3C, 4C, and 5C denote columns of the light-emitting diode groups PXG.

The light-emitting diode groups PXG arranged in the same column may be respectively electrically connected to the sub-pixel circuit groups arranged in the same column.

As an example, the light-emitting diode groups PXG in the first column 1C may be respectively electrically connected to the sub-pixel circuit groups PGA1, PGA2, PGA3, and PGA4 in the first column, described with reference to FIG. 8A. Among the light-emitting diode groups PXG in the first column 1C, some of the light-emitting diode groups PXG arranged in the third display area DA3 may be respectively electrically connected to some of the sub-pixel circuit groups PGA1, PGA2, and PGA3 described with reference to FIG. 8A. Among the light-emitting diode groups PXG in the first column 1C, the light-emitting diode group PXG arranged in the second display area DA2 may be electrically connected to the sub-pixel circuit group PGA4 arranged in the first column 1A, described with reference to FIG. 8A. Among the light-emitting diode groups PXG in the first column 1C, the light-emitting diode group PXG arranged in the second display area DA2 may be electrically connected to the sub-pixel circuit group PGA4 arranged in the first column 1A by a conductive bus line described above with reference to FIG. 3.

The light-emitting diode groups PXG in the second column 2C may be respectively electrically connected to the sub-pixel circuit groups PGB1, PGB2, PGB3, and PGB4 in the second column 2A, described with reference to FIG. 8A. The light-emitting diode groups PXG in the third column 3C may be respectively electrically connected to the sub-pixel circuit groups PGC1, PGC2, PGC3, and PGC4 in the third column 3A, described with reference to FIG. 8A. The light-emitting diode groups PXG in the fourth column 4C may be respectively electrically connected to the sub-pixel circuit groups PGD3 and PGD4 in the fourth column 4A, described with reference to FIG. 8A. The light-emitting diode groups PXG in the fifth column 5C may be respectively electrically connected to the sub-pixel circuit group PGE4 in the fifth column 5A, described with reference to FIG. 8A.

Referring to FIGS. 8A, 8B, and 8C, each sub-pixel circuit group arranged in the third display area DA3 includes three sub-pixel circuits. The three sub-pixel circuits may each be electrically connected to the plurality of second or third light-emitting diodes (one-to-many correspondence). As an example, among the three sub-pixel circuits of each sub-pixel circuit group shown in FIG. 8A, one sub-pixel circuit may be electrically connected to two green light-emitting diodes (one-to-two correspondence) connected by a first connection line PWL1, another sub-pixel circuit may be electrically connected to two red light-emitting diodes (one-to-two correspondence) connected by a second connection line PWL2, and the other sub-pixel circuit may be electrically connected to two blue light-emitting diodes (one-to-two correspondence) connected by a third connection line PWL3.

As an example, one the sub-pixel circuit groups PGA1, PGA2, and PGA2 arranged on the first column 1A in the third display area DA3, includes three third sub-pixel circuits PC3. One of the three third sub-pixel circuits PC3 may be electrically connected to one of two third green light-emitting diodes ED3g, and one of the three green light-emitting diodes ED3g may be electrically connected to the other third green light-emitting diode ED3g through a first connection line PWL1 including a light transmissive conductive material. As described above, the two third green light-emitting diodes ED3g electrically connected to each other through the first connection line PWL1 may be electrically connected to one third sub-pixel circuit PC3. Similarly, another third sub-pixel circuit PC3 among the three third sub-pixel circuits PC3 may be electrically connected to two third red light-emitting diodes ED3r connected to each other through the second connection line PWL2. One remaining third sub-pixel circuit PC3 among the three third sub-pixel circuits PC3 may be electrically connected to two third blue light-emitting diodes ED3b connected to each other through the third connection line PWL3.

The sub-pixel circuit group PGA4 arranged in the first column 1A in the third display area DA3 and adjacent to the second display area DA2 may include three second sub-pixel circuits PC2. The second sub-pixel circuits PC2 of the sub-pixel circuit group PGA4 adjacent to the second display area DA2 may be electrically connected to the second light-emitting diodes ED2 located in the second display area DA2.

Three second sub-pixel circuits PC2 included in the sub-pixel circuit group PGA4 arranged in the first column 1A and adjacent to the second display area DA2 may be electrically connected to the second light-emitting diodes ED2 of the light-emitting diode group PXG arranged in the first column 1C and located in the second display area DA2. As an example, one of three second sub-pixel circuits PC2 of the sub-pixel circuit group PGA4, may be electrically connected to two second green light-emitting diodes ED2g of the light-emitting diode group PXG1 in the second display area DA2, another second sub-pixel circuit PC2 may be electrically connected to two second red light-emitting diodes ED2r, and the other second sub-pixel circuit PC2 may be electrically connected to two second blue light-emitting diodes ED2b.

Referring to FIGS. 8B and 8C, the number of first light-emitting diodes ED1 arranged in an arbitrary region having a first area in the first display area DA1 may be greater than the number of second light-emitting diodes ED2 arranged in an arbitrary region having a first area in the second display area DA2. The number of first light-emitting diodes ED1 arranged in an arbitrary region having a first area in the first display area DA1 may be greater than the number of third light-emitting diodes ED3 arranged in an arbitrary region having a first area in the third display area DA3.

Because the number of second light-emitting diodes ED2 arranged in the second display area DA2 is less than the number of first light-emitting diodes ED1 arranged in the first display area DA1 per the same area, a portion of the transmissive area TA in the second display area DA2 may be relatively increased. In contrast, because the number of second light-emitting diodes ED2 arranged in the second display area DA2 is less than the number of first light-emitting diodes ED1 arranged in the first display area DA1 per the same area, the resolution and/or brightness of the first display area DA1 may be different from the resolution and/or brightness of the second display area DA2. However, according to an embodiment, the size of the light-emitting diodes relatively less arranged per the same area may be further increased.

As an example, the above issue may be reduced by increasing the size of the light-emitting diode of the first color, for example, the size of the second green light-emitting diode ED2g (e.g., the size of the emission area of the second green light-emitting diode ED2g). In other words, the size (or the width) of the emission area of the second green light-emitting diode ED2g may be greater than the size (or the width) of the emission area of the first green light-emitting diode ED1g.

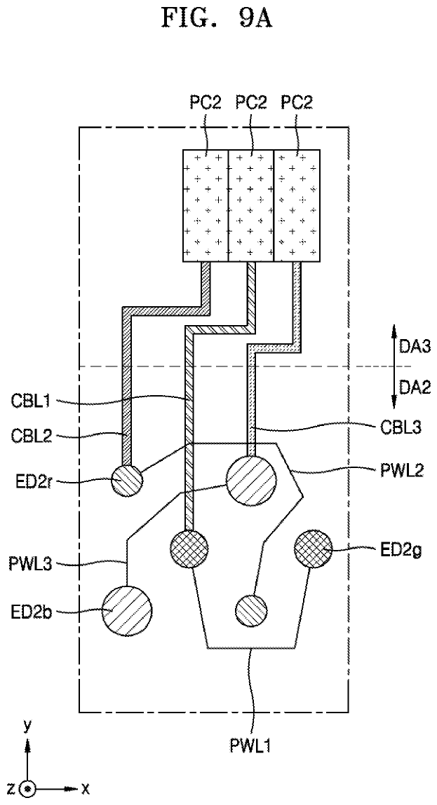

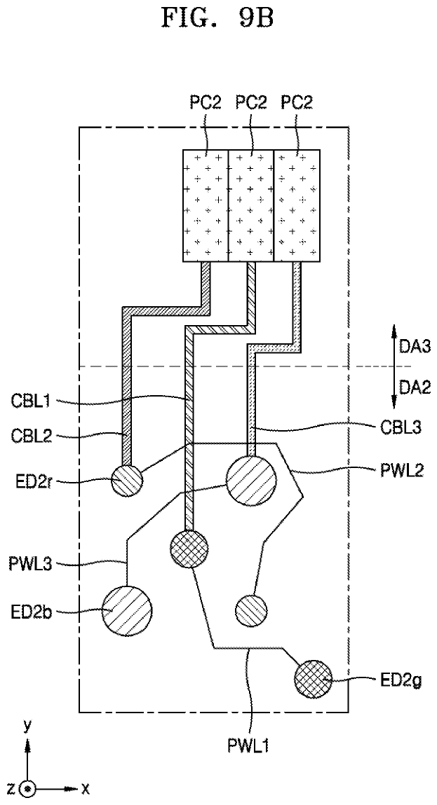

FIGS. 9A and 9B are plan views showing second light-emitting diodes of the display panel 10 are electrically connected to second sub-pixel circuits through conductive bus lines according to an embodiment.

Each second sub-pixel circuit PC2 arranged in the third display area DA3 may be electrically connected to the plurality of second light-emitting didoes configured to emit light of the same color. With regard to this, it is shown in FIGS. 9A and 9B that one second sub-pixel circuit PC2 is electrically connected to two second green light-emitting didoes ED2g through a first conductive bus line CBL1, another second sub-pixel circuit PC2 is electrically connected to two second red light-emitting didoes ED2r through a second conductive bus line CBL2, and still another second sub-pixel circuit PC2 is electrically connected to two second blue light-emitting didoes ED2b through a third conductive bus line CBL3.

The first conductive bus line CBL1 may extend from the third display area DA3 to the second display area DA2. A portion of the first conductive bus line CBL1 may be electrically connected to the second sub-pixel circuit PC2, and another portion of the first conductive bus line CBL1 may be electrically connected to one of two second green light-emitting diodes ED2g. The second green light-emitting diode ED2g connected to the first conductive bus line CBL1, of the two second green light-emitting diodes ED2g may be connected to the other second green light-emitting diode ED2g through the first connection line PWL1.

The second conductive bus line CBL2 may extend from the third display area DA3 to the second display area DA2. A portion of the second conductive bus line CBL2 may be electrically connected to the second sub-pixel circuit PC2, and another portion of the second conductive bus line CBL2 may be electrically connected to one of two second red light-emitting diodes ED2r. The second red light-emitting diode ED2r connected to the second conductive bus line CBL2, of the two second red light-emitting diodes ED2r may be connected to the other second red light-emitting diode ED2r through the second connection line PWL2.

The third conductive bus line CBL3 may extend from the third display area DA3 to the second display area DA2. A portion of the third conductive bus line CBL3 may be electrically connected to the second sub-pixel circuit PC2, and another portion of the third conductive bus line CBL3 may be electrically connected to one of two second blue light-emitting diodes ED2b. The second blue light-emitting diode ED2b connected to the third conductive bus line CBL3, of the two second blue light-emitting diodes ED2b may be connected to the other second blue light-emitting diode ED2b through the third connection line PWL3.

The first to third conductive bus lines CBL1, CBL2, and CBL3 may include a light transmissive conductive material. According to an embodiment, a portion of the transmissive area TA in the second display area DA2 may be maintained. As an example, the first to third conductive bus lines CBL1, CBL2, and CBL3 may include a transparent conducting oxide (TCO). The transparent conductive oxide may include a conductive oxide such as indium tin oxide (ITO), indium zinc oxide (IZO), zinc oxide (ZnO), indium oxide (In2O3), indium gallium oxide (IGO), indium zinc gallium oxide, and/or aluminum zinc oxide (AZO).

The first to third connection lines PWL1, PWL2, and PWL3 may have light-transmitting properties. Accordingly, a portion of the transmissive area TA in the second display area DA2 may be maintained. As an example, the first to third connection lines PWL1, PWL2, and PWL3 may include transparent conductive oxide. In an embodiment, the first to third connection lines PWL1, PWL2, and PWL3 may include the same material as a material forming a first electrode (e.g., an anode) of the light-emitting diode.

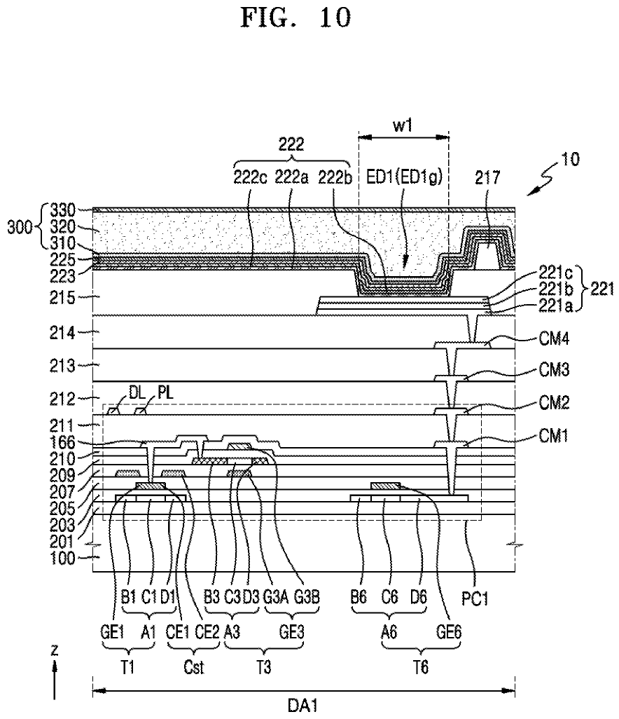

FIG. 10 is a cross-sectional view of the display panel 10 according to an embodiment and shows electrical connection between a first sub-pixel circuit and a first light-emitting diode. For convenience of description, it is described in FIG. 10 that the first light-emitting diode is the first green light-emitting diode ED1g.

Referring to FIG. 10, the first sub-pixel circuit PC1 disposed over the substrate 100, and the first light-emitting diode ED1 over the first sub-pixel circuit PC1, for example, the first green light-emitting diode ED1g may be located in the first display area DA1 of the display panel 10. The substrate 100 may include glass or polymer resin.

A buffer layer 201 may be disposed on the upper surface of the substrate 100. The buffer layer 201 may prevent impurities from penetrating a semiconductor layer of a transistor. The buffer layer 201 may include an inorganic insulating material such as silicon nitride, silicon oxynitride, and silicon oxide, and include a single layer or a multi-layer including the above inorganic insulating materials.

The first sub-pixel circuit PC1 may be disposed on the buffer layer 201. As described above with reference to FIG. 4, the first sub-pixel circuit PC1 may include the plurality of transistors and the storage capacitor. With regard to this, FIG. 10 shows the first transistor T1, the third transistor T3, the sixth transistor T6, and the storage capacitor Cst.

The first transistor T1 may include a first semiconductor layer A1 and a first gate electrode GE1, wherein the first semiconductor layer A1 is on the buffer layer 201, and the first gate electrode GE1 overlaps a channel region C1 of the first semiconductor layer A1. The first semiconductor layer A1 may include a silicon-based semiconductor material, for example, polycrystalline silicon. The first semiconductor layer A1 may include the channel region C1, a first region B1, and a second region D1 respectively arranged on two opposite sides of the channel region C1. The first region B1 and the second region D1 are regions including impurities of higher concentration than the concentration of the channel region C1. One of the first region B1 and the second region D1 may correspond to a source region, and the other may correspond to a drain region.

The sixth transistor T6 may include a sixth semiconductor layer A6 and a sixth gate electrode GE6, wherein the sixth semiconductor layer A6 is on the buffer layer 201, and the sixth gate electrode GE6 overlaps a channel region C6 of the sixth semiconductor layer A6. The sixth semiconductor layer A6 may include a silicon-based semiconductor material, for example, polycrystalline silicon. The sixth semiconductor layer A6 may include the channel region C6, a first region B6, and a second region D6 respectively arranged on two opposite sides of the channel region C6. The first region B6 and the second region D6 are regions including impurities of higher concentration than the concentration of the channel region C6. One of the first region B6 and the second region D6 may correspond to a source region, and the other may correspond to a drain region.

The first gate electrode GE1 and the sixth gate electrode GE6 may include a conductive material including molybdenum (Mo), aluminum (Al), copper (Cu), and/or titanium (Ti) and have a single-layered structure or a multi-layered structure including the above materials. A first gate insulating layer 203 may be disposed below the first gate electrode GE1 and the sixth gate electrode GE6, wherein the first gate insulating layer 203 is for electrical insulation between the first semiconductor layer A1 and the first gate electrode GE1 and between the sixth semiconductor layer A6 and the sixth gate electrode GE6. The first gate insulating layer 203 may include an inorganic insulating material such as silicon nitride, silicon oxynitride, and/or silicon oxide, and include a single layer or a multi-layer including the above inorganic insulating materials.

The storage capacitor Cst may include the lower electrode CE1 and the upper electrode CE2 overlapping each other. In an embodiment, the lower electrode CE1 of the storage capacitor Cst may include the first gate electrode GE1. In other words, the first gate electrode GE1 may include the lower electrode CE1 of the storage capacitor Cst. As an example, the first gate electrode GE1 and the lower electrode CE1 of the storage capacitor Cst may be one body.

A first interlayer insulating layer 205 may be disposed between the lower electrode CE1 and the upper electrode CE2 of the storage capacitor Cst. The first interlayer insulating layer 205 may include an inorganic insulating material such as silicon nitride, silicon oxynitride, and silicon oxide, and include a single-layered structure or a multi-layered structure including the above inorganic insulating materials.

The upper electrode CE2 of the storage capacitor Cst may include a conductive material of a low-resistance material such as molybdenum (Mo), aluminum (Al), copper (Cu) and/or titanium (Ti), and have a single-layered structure or a multi-layered structure including the above materials.

A second interlayer insulating layer 207 may be disposed on the storage capacitor Cst. The second interlayer insulating layer 207 may include an inorganic insulating material such as silicon nitride, silicon oxynitride, and/or silicon oxide, and include a single-layered structure or a multi-layered structure including the above inorganic insulating materials.

A third semiconductor layer A3 of the third transistor T3 may be disposed on the second interlayer insulating layer 207. The third semiconductor layer A3 may include an oxide-based semiconductor material. As an example, the third semiconductor layer A3 may include Zn-oxide-based material, for example, include Zn-oxide, In—Zn oxide, and/or Ga—In—Zn oxide. In an embodiment, the third semiconductor layer A3 may include In—Ga—Zn—O (IGZO), In—Sn—Zn—O (ITZO), or In—Ga—Sn—Zn—O (IGTZO) semiconductor containing metal such as indium (In), gallium (Ga), and stannum (Sn) in ZnO.

The third semiconductor layer A3 may include a channel region C3, a first region B3, and a second region D3 respectively arranged on two opposite sides of the channel region C3. One of the first region B3 and the second region D3 may correspond to a source region, and the other may correspond to a drain region.

The third transistor T3 may include a third gate electrode GE3 overlapping the channel region C3 of the third semiconductor layer A3. The third gate electrode GE3 may have a double gate structure including a lower gate electrode G3A and an upper gate electrode G3B, wherein the lower gate electrode G3A is below the third semiconductor layer A3, and the upper gate electrode G3B is over the channel region C3.

The lower gate electrode G3A may be on the same layer (e.g., the first interlayer insulating layer 205) as a layer on which the upper electrode CE2 of the storage capacitor Cst is arranged. The lower gate electrode G3A may include the same material as a material of the upper electrode CE2 of the storage capacitor Cst.

The upper gate electrode G3B may be disposed over the third semiconductor layer A3 with a second gate insulating layer 209 therebetween. The second gate insulating layer 209 may include an inorganic insulating material such as silicon nitride, silicon oxynitride, and/or silicon oxide, and include a single-layered structure or a multi-layered structure including the above inorganic insulating materials.

A third interlayer insulating layer 210 may be disposed on the upper gate electrode G3B. The third interlayer insulating layer 210 may include an inorganic insulating material such as silicon oxynitride, and have a single layer or a multi-layer including the inorganic insulating materials.

Though it is shown in FIG. 10 that the upper electrode CE2 of the storage capacitor Cst is arranged on the same layer as the lower gate electrode G3A of the third gate electrode GE3, the embodiment is not limited thereto. In another embodiment, the upper electrode CE2 of the storage capacitor Cst may be arranged on the same layer as the third semiconductor layer A3, and may include the same material as that of the first region B3 and the second region D3 of the third semiconductor layer A3.

The first transistor T1 may be electrically connected to the third transistor T3 through the node connection line 166. The node connection line 166 may be disposed on the third interlayer insulating layer 210. One side of the node connection line 166 may be connected to the first gate electrode GE1 of the first transistor T1, and another side of the node connection line 166 may be connected to the first region B3 of the third semiconductor layer A3 of the third transistor T3.

The node connection line 166 may include aluminum (Al), copper (Cu), and/or titanium (Ti), and include a single layer or a multi-layer including the above materials. As an example, the node connection line 166 may have a triple-layered structure of titanium layer/aluminum layer/titanium layer.

A first organic insulating layer 211 may be disposed on the node connection line 166. The first organic insulating layer 211 may include an organic insulating material. The organic insulating material may include acryl, benzocyclobutene (BCB), polyimide, and/or hexamethyldisiloxane (HMDSO).

The data line DL and the driving voltage line PL may be disposed on the first organic insulating layer 211. The data line DL and the driving voltage line PL may include aluminum (Al), copper (Cu), and/or titanium (Ti), and include a single layer or a multi-layer including the above materials. As an example, the data line DL and the driving voltage line PL may each have a triple-layered structure of titanium layer/aluminum layer/titanium layer.

Though it is shown in FIG. 10 that the data line DL and the driving voltage line PL are disposed on the same layer (e.g., the first organic insulating layer 211), the data line DL and the driving voltage line PL may be disposed on different layers in another embodiment.

A second organic insulating layer 212, a third organic insulating layer 213, and a fourth organic insulating layer 214 may be disposed on the first organic insulating layer 211. The second organic insulating layer 212, the third organic insulating layer 213, and the fourth organic insulating layer 214 may each include an organic insulating material such as acryl, benzocyclobutene, polyimide, or hexamethyldisiloxane (HMDSO).

A first electrode 221 of the first light-emitting diode ED1 may be disposed on the fourth organic insulating layer 214. The first electrode 221 may be electrically connected to the sixth transistor T6 through first to fourth connection metals CM1, CM2, CM3, and CM4. The first connection metal CM1 may be formed on the same layer (e.g., the third interlayer insulating layer 210) as a layer of the node connection line 166, and may include the same material as a material of the node connection line 166. The second connection metal CM2 may be formed on the same layer (e.g., the first organic insulating layer 211) as the data line DL and/or the driving voltage line PL and may include the same material as a material of the data line DL and/or the driving voltage line PL. The third connection metal CM3 and the fourth connection metal CM4 may include a conductive material, for example, metal (e.g., metal having no light transmittance) or a conductive material having a light transmittance. The third connection metal CM3 may be disposed on the second organic insulating layer 212, and the fourth connection metal CM4 may be disposed on the third organic insulating layer 213.

The first electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the first electrode 221 may further include a conductive oxide material layer on and/or under the reflective layer. The conductive oxide material layer may include indium tin oxide (ITO), indium zinc oxide (IZO), zinc oxide (ZnO), indium oxide (In2O3), indium gallium oxide (IGO), and/or aluminum zinc oxide (AZO). In an embodiment, the first electrode 221 may include a plurality of sub-layers. As an example, the first electrode 221 may include first to third sub-layers 221a, 221b, and 221c. The first to third sub-layers 221a, 221b, and 221c may respectively be an ITO layer, an Ag layer, and an ITO layer.

A bank layer 215 may be disposed on the first electrode 221. The bank layer 215 may include an opening that overlaps the first electrode 221 and cover the edges of the first electrode 221. The bank layer 215 may include an organic insulating material such as polyimide. The opening of the bank 215 may define the emission area of the light-emitting diode, and the size (or the width) of the emission area of the light-emitting diode corresponds to the size (or the width) of the sub-pixel. As an example, the width of the bank layer 215 shown in FIG. 10 may define the width w1 of the emission area of the first green light-emitting diode ED1g, and the width w1 of the emission area of the first green light-emitting diode ED1g corresponds to the width of a green sub-pixel in the first display area DA1.

A spacer 217 may be formed on the bank layer 215. The spacer 217 may be formed together during the same process as a process of forming the bank layer 215, or formed separately during a separate process. In an embodiment, the spacer 217 may include an organic insulating material such as polyimide. In another embodiment, the bank layer 215 may include an organic insulating material including a light-blocking dye, and the spacer 217 may include an organic insulating material such as polyimide.

An intermediate layer 222 includes an emission layer 222b. The intermediate layer 222 may include a first functional layer 222a and/or a second functional layer 222c, wherein the first functional layer 222a is under the emission layer 222b, and the second functional layer 222c is on the emission layer 222b. The emission layer 222b may include a polymer organic material or a low-molecular weight organic material emitting light having a preset color (red, green, or blue). In another embodiment, the emission layer 222b may include an inorganic material or quantum dots.

The second functional layer 222c may include an electron transport layer (ETL) and/or an electron injection layer (EIL). The first functional layer 222a and the second functional layer 222c may each include an organic material.

The emission layer 222b may be formed in the first display area DA1 to overlap the first electrode 221 through the opening of the bank layer 215. In contrast, an organic material layer, for example, the first functional layer 222a and the second functional layer 222c included in the intermediate layer, may cover the display area DA (see FIG. 3) entirely.

The intermediate layer 222 may have a single stack structure including a single emission layer, or a tandem structure, which is a multi-stack structure including a plurality of emission layers. In the case where the intermediate layer 222 has a tandem structure, a charge generation layer CGL may be disposed between the plurality of stacks.

A second electrode 223 may include a conductive material having a low work function. As an example, the second electrode 223 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the second electrode 223 may further include a layer on the (semi) transparent layer, the layer including ITO, IZO, ZnO, or In2O3. The second electrode 223 may cover the display area DA (see FIG. 3) entirely.

A capping layer 225 may be disposed on the second electrode 223. The capping layer 225 may include an inorganic material or an organic material. The capping layer 225 may include lithium fluoride (LiF), an inorganic insulating material and/or an organic insulating material. The capping layer 225 may cover the display area DA entirely.

The first light-emitting diode ED1 may be covered by the encapsulation layer 300. The encapsulation layer 300 may include at least one organic encapsulation layer and at least one inorganic encapsulation layer. In an embodiment, it is shown in FIG. 5 that the encapsulation layer 300 includes first and second inorganic encapsulation layers 310 and 330, and an organic encapsulation layer 320 therebetween. The encapsulation layer 300 may be disposed on the capping layer 225.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The first and second inorganic encapsulation layer 310 and 330 may include a single layer or a multi-layer including the above materials. The organic encapsulation layer 320 may include a polymer-based material. The polymer-based material may include an acryl-based resin, an epoxy-based resin, polyimide, and polyethylene. In an embodiment, the organic encapsulation layer 320 may include acrylate.

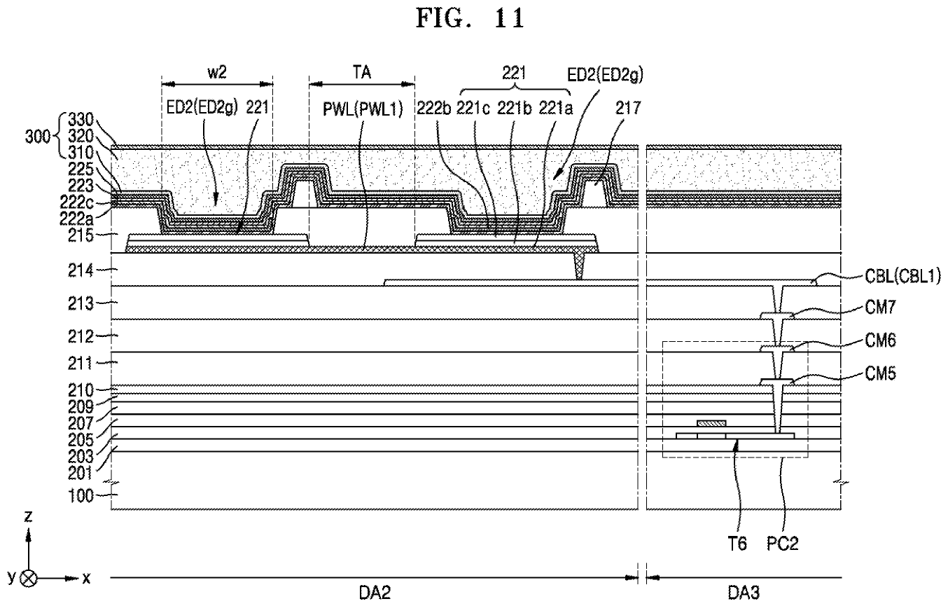

FIG. 11 is a cross-sectional view of the display panel 10 according to an embodiment and shows electrical connection between a second sub-pixel circuit and a second light-emitting diode. For convenience of description, it is described in FIG. 11 that the second light-emitting diode is the second green light-emitting diode ED2g.

Referring to FIG. 11, the second sub-pixel circuit PC2 on the substrate 100 may be arranged in the third display area DA3, and the second light-emitting diode ED2, for example, the second green light-emitting diode ED2g electrically connected to the second sub-pixel circuit PC2 may be arranged in the second display area DA2. As described above with reference to FIG. 4, the second sub-pixel circuit PC2 may include the plurality of transistors and the storage capacitor. With regard to this, FIG. 11 shows the sixth transistor T6 of the second sub-pixel circuit PC2. The buffer layer 210, the first gate insulating layer 203, the first interlayer insulating layer 205, the second interlayer insulating layer 207, the second gate insulating layer 209, the third interlayer insulating layer 210, and the first to fourth organic insulating layers 211, 212, 213, and 214, may be disposed on the substrate 100.

The second sub-pixel circuit PC2 may be electrically connected to the second light-emitting diode ED2 through the conductive bus line CBL extending from the third display area DA3 to the second display area DA2. With regard to this, it is shown in FIG. 11 that the second sub-pixel circuit PC2 is electrically connected to the second green light-emitting diode ED2g through the first conductive bus line CBL1 extending from the third display area DA3 to the second display area DA2.

The first conductive bus line CBL1 may be electrically connected to the sixth transistor T6 of the second sub-pixel circuit PC2 through the fifth to seventh connection metals CM5, CM6, and CM7. The fifth connection metal CM5 may be formed on the same layer as the first connection metal CM1 (see FIG. 10) and may include the same material as a material of the first connection metal CM1 (see FIG. 10). The sixth connection metal CM6 may be formed on the same layer as the second connection metal CM2 (see FIG. 10) and may include the same material as a material of the second connection metal CM2 (see FIG. 10). The seventh connection metal CM7 may be formed on the same layer as the third connection metal CM3 (see FIG. 10) and may include the same material as a material of the third connection metal CM3 (see FIG. 10).

The bank layer 215 and a spacer 217 may be disposed on the first electrode 221 of the second light-emitting diode ED2, wherein the bank layer 215 includes an opening that overlaps the first electrode 221. The opening of the bank layer 215 may defined the emission area of the second light-emitting diode ED2. As an example, as shown in FIG. 11, the opening of the bank layer 215 may define the width w2 of the emission area of the second green light-emitting diode ED2g. The width w2 of the emission area of the second green light-emitting diode ED2g is greater than the width w1 of the emission area of the first green light-emitting diode ED1g.

The first functional layer 222a, the emission layer 222b, the second functional layer 222c, the second electrode 223, the capping layer 225, and the encapsulation layer 300 may be disposed on the first electrode 221. The first functional layer 222a, the emission layer 222b, the second functional layer 222c, the second electrode 223, the capping layer 225, and the encapsulation layer 300 are the same as those described with reference to FIG. 10. As described above with reference to FIG. 10, the first electrode 221 may include the first sub-layer 221a including ITO, the second sub-layer 221b including Ag, and the third sub-layer 221c including ITO.

Through the conductive bus line CBL, the second sub-pixel circuit PC2 may be electrically connected to the second light-emitting diodes ED2 of the same color electrically connected to each other through the connection line PWL. With regard to this, it is shown in FIG. 11 that one of the second sub-pixel circuits PC2 is electrically connected to the two second green light-emitting diodes ED2g through the first conductive bus line CBL1. In an embodiment, the first conductive bus line CBL1 may be electrically connected to the first electrode 221 of one of two second green light-emitting diodes ED2g, and the one second green light-emitting diode ED2g may be electrically connected to the other second green light-emitting diode ED2g through the first connection line PWL1.

The first connection line PWL1 may include the same material as a material of one of the plurality of sub-layers included in the first electrode 221. As an example, the first electrode 221 may include the first sub-layer 221a, the second sub-layer 221b, and the third sub-layer 221c, and the first connection line PWL1 may include the same material as a material of one of the sub-layers of the first electrode 221, for example, the first sub-layer 221a located in the lowermost portion. In an embodiment, the first connection line PWL1 and the first sub-layer 221a may include ITO. In an embodiment, the first connection line PWL1 and the first sub-layer 221a may include crystallized ITO. The first connection line PWL1 may be disposed on the same layer (e.g., the fourth organic insulating layer 214) as the first sub-layer 221a and be integrally coupled to the first sub-layer 221a.

According to an embodiment, provided are the display panel having high quality in which the area and transmission rate of the transmissive area of the second display area including the transmissive area may be sufficiently secured, and image quality may be maintained regardless of the position of the second display area in the display area, and an electronic apparatus including the display panel. However, this effect is an example, and the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a plurality of first light-emitting diodes arranged in a first display area;
a plurality of first sub-pixel circuits arranged in the first display area and respectively electrically connected to the plurality of first light-emitting diodes;
a plurality of second light-emitting diodes arranged in a second display area inside the first display area and including a transmissive area; and
a plurality of second sub-pixel circuits arranged in an area different from the second display area and respectively electrically connected to the plurality of second light-emitting diodes,
wherein the plurality of first light-emitting diodes and the plurality of second light-emitting diodes each include light-emitting diodes of a first color, light-emitting diodes of a second color, and light-emitting diodes of a third color, and
a first width of an emission area of a light-emitting diode of the first color arranged in the second display area is greater than a second width of an emission area of a light-emitting diode of the first color arranged in the first display area.

2. The display panel of claim 1, wherein a first electrode of the light-emitting diode of the first color, arranged in the second display area is electrically connected to a first electrode of an adjacent light-emitting diode of the first color through a first connection line.

3. The display panel of claim 2, wherein the first electrode of the light-emitting diode of the first color and the first electrode of the adjacent light-emitting diode of the first color each include a plurality of sub-layers, and
the first connection line is integrally coupled to one of the plurality of sub-layers.

4. The display panel of claim 2, wherein the light-emitting diode of the first color and the adjacent light-emitting diode of the first color electrically connected to each other through the first connection line are electrically connected to one of the plurality of second sub-pixel circuits.

5. The display panel of claim 4, wherein the plurality of second sub-pixel circuits are arranged in a third display area between the first display area and the second display area.

6. The display panel of claim 5, further comprising a conductive bus line electrically connecting the light-emitting diode of the first color arranged in the second display area to one of the plurality of second sub-pixel circuits,
wherein the conductive bus line extends from the third display area to the second display area.

7. The display panel of claim 6, wherein the conductive bus line includes a light transmissive conductive material.

8. The display panel of claim 1, wherein the first width of the emission area of the light-emitting diode of the first color arranged in the second display area is greater than a width of an emission area of the light-emitting diode of the second color arranged in the second display area, and
the second width of the emission area of the light-emitting diode of the first color arranged in the first display area is less than a width of an emission area of the light-emitting diode of the second color arranged in the first display area.

9. The display panel of claim 1, wherein a number of light-emitting diodes of the first color arranged in the second display area is less than a number of light-emitting diodes of the first color arranged in the first display area per same area,
a number of light-emitting diodes of the second color arranged in the second display area is equal to a number of light-emitting diodes of the second color arranged in the first display area per same area, and
a number of light-emitting diodes of the third color arranged in the second display area is equal to a number of light-emitting diodes of the third color arranged in the first display area per same area.

10. The display panel of claim 14, wherein light-emitting diodes of the first color around the light-emitting diode of the second color in the second display area are located at only two vertexes among four vertexes of a virtual quadrangle with the light-emitting diode of the second color centered in the second display area.

11. The display panel of claim 10, wherein light-emitting diodes of the first color around the light-emitting diode of the second color in the first display area are respectively located at four vertexes of a virtual quadrangle with the light-emitting diode of the second color centered in the first display area.

12. An electronic apparatus comprising:
a display panel including a first display area, a second display area, and a third display area, the second display area being surrounded by the first display area, and the third display area being between the first display area and the second display area; and
a component disposed below the display panel and corresponding to the second display area,
wherein the display panel includes:
a plurality of first light-emitting diodes arranged in the first display area;
a plurality of first sub-pixel circuits arranged in the first display area and respectively electrically connected to the plurality of first light-emitting diodes;
a plurality of second light-emitting diodes arranged in the second display area; and
a plurality of second sub-pixel circuits arranged in the third display area and respectively electrically connected to the plurality of second light-emitting diodes,
wherein the plurality of first light-emitting diodes and the plurality of second light-emitting diodes each include light-emitting diodes of a first color, light-emitting diodes of a second color, and light-emitting diodes of a third color, and
a first width of an emission area of a light-emitting diode of the first color arranged in the second display area is greater than a second width of an emission area of a light-emitting diode of the first color arranged in the first display area.

13. The electronic apparatus of claim 12, wherein a number of light-emitting diodes of the first color arranged in the second display area is less than a number of light-emitting diodes of the first color arranged in the first display area per same area.

14. The electronic apparatus of claim 12, wherein a first electrode of the light-emitting diode of the first color, arranged in the second display area is electrically connected to a first electrode of an adjacent light-emitting diode of the first color through a first connection line.

15. The electronic apparatus of claim 14, wherein the first electrode of the light-emitting diode of the first color and the first electrode of the adjacent light-emitting diode of the first color each include a plurality of sub-layers, and
the first connection line is integrally coupled to one of the plurality of sub-layers.

16. The electronic apparatus of claim 14, wherein the first electrode of the light-emitting diode of the first color is electrically connected to one of the plurality of second sub-pixel circuits through a conductive bus line extending from the third display area to the second display area.

17. The electronic apparatus of claim 16, wherein the conductive bus line includes a light transmissive conductive material.

18. The electronic apparatus of claim 16, wherein light-emitting diodes of the first color around the light-emitting diode of the second color in the second display area are located at only two vertexes among four vertexes of a virtual quadrangle with the light-emitting diode of the second color centered in the second display area.

19. The electronic apparatus of claim 18, wherein light-emitting diodes of the first color around the light-emitting diode of the second color in the first display area are respectively located at four vertexes of a virtual quadrangle with the light-emitting diode of the second color centered in the first display area.

20. The electronic apparatus of claim 12, wherein the component includes a sensor or a camera.
